(19) United States
(12) Patent Application Publication
(10) Pub. No.: US 2025/0338693 A1
(43) Pub. Date: Oct. 30, 2025

(54) DISPLAY APPARATUS AND METHOD OF MANUFACTURING THE SAME

(71) Applicant: SAMSUNG ELECTRONICS CO., LTD., Suwon-si (KR)

(72) Inventors: Junhee CHOI, Suwon-si (KR); Nakhyun KIM, Suwon-si (KR); Joohun HAN, Suwon-si (KR)

(73) Assignee: SAMSUNG ELECTRONICS CO., LTD., Suwon-si (KR)

(21) Appl. No.: 19/018,494

(22) Filed: Jan. 13, 2025

(30) Foreign Application Priority Data
Apr. 29, 2024 (KR) 10-2024-0057084

(51) Int. Cl. H10H 29/851; H10H 20/825; H10H 29/01; H10H 29/34; H10H 29/80

(52) U.S. Cl. CPC H10H 29/8514; H10H 29/012; H10H 29/0361; H10H 29/34; H10H 29/8421; H10H 29/8512; H10H 20/825

(57) ABSTRACT

A display apparatus includes a backplane substrate including driving elements, and a first light-emitting section, a second light-emitting section, and a third light-emitting section spaced apart from each other on the backplane substrate, the first light-emitting section being configured to emit light of a first wavelength, the second light-emitting section being configured to emit light of a second wavelength, and the third light-emitting section being configured to emit light of a third wavelength, where each of the first light-emitting section, the second light-emitting section and the third light-emitting section includes a p-type semiconductor layer, an active layer configured to emit blue light, and an n-type semiconductor layer stacked in a direction perpendicular to an upper surface of the backplane substrate.

### CROSS-REFERENCE TO RELATED APPLICATION

This application is based on and claims priority under 35 U.S.C. § 119 to Korean Patent Application No. 10-2024-0057084, filed on Apr. 29, 2024, in the Korean Intellectual Property Office, the disclosure of which is incorporated by reference herein in its entirety.

### BACKGROUND

### 1. Field

The disclosure relates to a display apparatus for displaying color images and a method of manufacturing the display apparatus.

### 2. Description of Related Art

Display apparatuses such as liquid crystal displays (LCDs) and organic light-emitting diode (OLED) displays are widely used. Recently, techniques using micro light-emitting diodes (LEDs) for manufacturing high-resolution display apparatuses have gained attention. LEDs generally may consume low power and are environmentally friendly, thereby increasing industrial demand for LEDs.

Micro-sized or nano-sized ultra-small LEDs using Group II-VI or III-V compound semiconductors have been developed. However, when LEDs are miniaturized to these micro scales or nano scales, the luminous efficiency of LEDs decreases.

### SUMMARY

Provided are a display apparatus capable of achieving high luminous efficiency and a method of manufacturing the same.

Additional aspects will be set forth in part in the description which follows and, in part, will be apparent from the description, or may be learned by practice of the presented embodiments of the disclosure.

According to an aspect of the disclosure, a display apparatus may include a backplane substrate including driving elements, and a first light-emitting section, a second light-emitting section, and a third light-emitting section spaced apart from each other on the backplane substrate, the first light-emitting section being configured to emit light of a first wavelength, the second light-emitting section being configured to emit light of a second wavelength, and the third light-emitting section being configured to emit light of a third wavelength, where each of the first light-emitting section, the second light-emitting section and the third light-emitting section includes a p-type semiconductor layer, an active layer configured to emit blue light, and an n-type semiconductor layer stacked in a direction perpendicular to an upper surface of the backplane substrate, and each of the n-type semiconductor layers of the first light-emitting section and the third light-emitting section includes a core rod, a plurality of nanopores respectively comprising an opening and extending from the core rod, and quantum dots in the plurality of nanopores.

The quantum dots of the first light-emitting section may be configured to convert blue light into red light, and the quantum dots of the third light-emitting section may be configured to convert blue light into green light.

The display apparatus may include p-type electrodes between the backplane substrate and respective p-type semiconductor layers, and an n-type electrode commonly connected to the first light-emitting section, the second light-emitting section and the third light-emitting section.

The display apparatus may include a first bonding layer between the backplane substrate and the first light-emitting section, a second bonding layer between the backplane substrate and the second light-emitting section, and a third bonding layer between the backplane substrate and the third light-emitting section.

The plurality of nanopores of each of the first light-emitting section and the third light-emitting section may extend radially outward from each respective core rod.

The plurality of nanopores of each of the first light-emitting section and the third light-emitting section may be substantially aligned along a vertical direction.

Each of the active layers may include InGaN or InAlGaN.

Each of the first light-emitting section, the second light-emitting section and the third light-emitting section may have a diameter in a range of 0.5 μm to 2 μm.

Each of the first light-emitting section, the second light-emitting section and the third light-emitting section may have a height in a range of 2 μm to 7 μm.

Each of the core rods may have a diameter in a range of ⅓ to ⅕ of a diameter of a respective light-emitting section.

Each of the core rods may have a diameter in a range of 120 nm to 200 nm.

The display apparatus may include a distributed Bragg reflection layer surrounding side walls of the first light-emitting section, the second light-emitting section and the third light-emitting section, where the distributed Bragg reflection layer may have a first reflectivity for blue light and a second reflectivity for green light and red light, the second reflectivity being lower than the first reflectivity.

The display apparatus may include reflection layers respectively on the n-type semiconductor layers of the first light-emitting section and the third light-emitting section, where the reflection layers may include aluminum (Al) or silver (Ag).

The display apparatus may include etching barriers between the backplane substrate and respective p-type semiconductor layers.

The etching barriers may include indium tin oxide (ITO).

According to an aspect of the disclosure, a method of manufacturing a display apparatus may include preparing a backplane substrate including a driving element and a first bonding layer, forming a stacked structure by depositing an active layer, a p-type semiconductor layer, and a second bonding layer on an n-type semiconductor layer, bonding the backplane substrate to the stacked structure in a state in which the first bonding layer of the backplane substrate faces the second bonding layer of the stacked structure, forming a first light-emitting section, a second light-emitting section, and a third light-emitting section that are spaced apart from each other by patterning the n-type semiconductor layer, the active layer, and the p-type semiconductor layer into a rod shape, forming a core rod and a plurality of nanopores in the n-type semiconductor layer of each of the first light-emitting section, the second light-emitting section and the third light-emitting section through an electrochemical etching process, the plurality of nanopores including an opening and extending from the core rod, forming a quantum dot patterning layer on the first light-emitting section, the second light-emitting section and the third light-emitting section, removing the quantum dot patterning layer from the first light-emitting section and forming quantum dots in the plurality of nanopores of the first light-emitting section, and removing the quantum dot patterning layer from the third light-emitting section and forming quantum dots in the plurality of nanopores of the third light-emitting section.

The quantum dots of the first light-emitting section may be configured to convert blue light into red light, and the quantum dots of the third light-emitting section may be configured to convert blue light into green light.

A p-type electrode may be provided between the backplane substrate and the p-type semiconductor layer, and an n-type electrode may be commonly connected to the first light-emitting section, the second light-emitting section and the third light-emitting section.

The plurality of nanopores of each of the first light-emitting section and the third light-emitting section may extend radially outward from the core rod.

The plurality of nanopores of each of the first light-emitting section and the third light-emitting section may be substantially aligned along a vertical direction.

According to an aspect of the disclosure, a display apparatus may include a backplane substrate, a first light-emitting section configured to emit light of a first wavelength, the first light-emitting section including a p-type semiconductor layer, an active layer on the p-type semiconductor layer, and an n-type semiconductor layer on the active layer, a second light-emitting section spaced apart from the first light-emitting section and configured to emit light of a second wavelength, the second light-emitting section including a p-type semiconductor layer, an active layer on the p-type semiconductor layer, and an n-type semiconductor layer on the active layer, and a third light-emitting section spaced apart from the first light-emitting section and the second light-emitting section, the third light-emitting section being configured to emit light of a third wavelength, and the third light-emitting section including a p-type semiconductor layer, an active layer on the p-type semiconductor layer, and an n-type semiconductor layer on the active layer, where each of the n-type semiconductor layers of the first light-emitting section and the third light-emitting section includes a core rod, a plurality of nanopore layers arranged in a direction perpendicular to an upper surface of the backplane substrate, and quantum dots in each of the plurality of nanopore layers.

The n-type semiconductor layer of the second light-emitting section may not include quantum dots.

The display apparatus may include first distributed Bragg reflection layer at least partially surrounding sidewalls of the first light-emitting section, where the active layer of the first light-emitting section is configured to emit blue light, the first distributed Bragg reflection layer is configured to reflect the blue light emitted from the active layer of the first light-emitting section inward toward the quantum dots of the first light-emitting section, and the quantum dots of the first light-emitting section are configured to convert the reflected blue light into red light.

The display apparatus may include a third distributed Bragg reflection layer at least partially surrounding sidewalls of the third light-emitting section, where the active layer of the third light-emitting section is configured to emit blue light, the third distributed Bragg reflection layer is configured to reflect the blue light emitted from the active layer of the third light-emitting section inward toward the quantum dots of the third light-emitting section, and the quantum dots of the third light-emitting section are configured to convert the reflected blue light into green light.

Each of the plurality of nanopore layers may include a plurality of nanopores, and each of the plurality of nanopores extends radially outward from the core rod of a respective light-emitting section and may include an opening at a sidewall of the respective light-emitting section.

Each of the plurality of nanopore layers may include a plurality of nanopores, and at least one nanopore of the plurality of nanopores in each of the nanopore layers are substantially aligned with at least one other nanopore of the plurality of nanopores in each of the nanopore layers along a direction perpendicular to an upper surface of the backplane substrate.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view illustrating a display apparatus according to an embodiment;

FIG. 2 is a cross-sectional view taken along line A-A′ of FIG. 1 according to an embodiment;

FIG. 3 is a cross-sectional view illustrating an example in which the display apparatus shown in FIG. 1 further includes reflection layers and etching barriers according to an embodiment;

FIG. 4 is a cross-sectional view illustrating an example in which boding layers of the display apparatus shown in FIG. 1 are modified according to an embodiment;

FIG. 5 is a cross-sectional view illustrating an example in which the bonding layers of the display apparatus shown in FIG. 1 are modified according to an embodiment;

FIGS. 6A to 6R are diagrams illustrating a method of manufacturing a display apparatus according to an embodiment;

FIGS. 7A to 7F are diagrams illustrating a method of manufacturing a display apparatus according to an embodiment;

FIGS. 8A to 8D are diagrams illustrating a method of manufacturing a display apparatus according to an embodiment;

FIG. 9 is a diagram illustrating an electronic device according to an embodiment;

FIG. 10 is a diagram illustrating a mobile device in which a display apparatus is applied according to an embodiment;

FIG. 11 is a diagram illustrating a vehicle display apparatus in which a display apparatus is applied according to an embodiment;

FIG. 12 is a diagram illustrating augmented reality (AR) glasses or virtual reality (VR) glasses in which a display apparatus is applied according to an embodiment;

FIG. 13 is a diagram illustrating signage in which a display apparatus is applied according to an embodiment; and

FIG. 14 is a diagram illustrating a wearable display in which a display apparatus is applied according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, display apparatuses and methods of manufacturing the display apparatuses will be described according to various embodiments with reference to the accompanying drawings. The embodiments described below are merely exemplary, and various modifications are possible from these embodiments. In the following drawings, the same reference numerals refer to the same components, and the size of each component in the drawings may be exaggerated for clarity and convenience of description.

Terms such as first, second, etc. may be used to describe various components, but are used only for the purpose of distinguishing one component from another component. These terms do not limit the difference in the material or structure of the components.

As used herein, singular forms may include plural forms as well unless the context clearly indicates otherwise. The use of the term “the” and similar designating terms may correspond to both the singular and the plural. It will be further understood that the terms “comprises,” “comprising,” “includes,” and/or “including” used herein specify the presence of stated features or elements, but do not preclude the presence or addition of one or more other features or elements.

In addition, terms such as “unit” and “module” described in the specification may indicate a unit that processes at least one function or operation, and this may be implemented as hardware or software, or may be implemented as a combination of hardware and software.

In the following description, when a component is referred to as being “above” or “on” another component, it may be directly on an upper, lower, left, or right side of the other component while making contact with the other component or may be above an upper, lower, left, or right side of the other component without making contact with the other component.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

Furthermore, in the following embodiments, a material included in each layer is an example, and another material may be used in addition to or instead of the material.

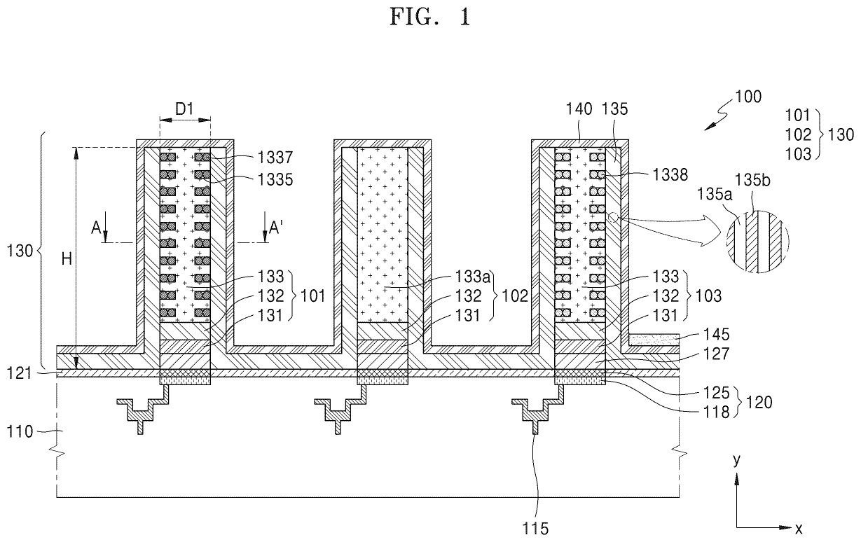

FIG. 1 is a cross-sectional view illustrating a display apparatus 100 according to an embodiment.

The display apparatus 100 includes a backplane substrate 110 including driving elements 115, and a light-emitting section array structure 130 provided on the backplane substrate 110. The light-emitting section array structure 130 may include a first light-emitting section 101, a second light-emitting section 102, and a third light-emitting section 103 that are spaced apart from each other. The first light-emitting section 101 is configured to emit first-color light (e.g., light of a first wavelength), the second light-emitting section 102 is configured to emit second-color light (e.g., light of a second wavelength), and the third light-emitting section 103 is configured to emit third-color light (e.g., light of a third wavelength). For example, the first-color light may be red light, the second-color light may be blue light, and the third-color light may be green light.

The driving elements 115 may be configured to drive the first light-emitting section 101, the second light-emitting section 102, and the third light-emitting section 103, and may each include at least one capacitor and at least one transistor.

The first light-emitting section 101 and the third light-emitting section 103 may each include a p-type semiconductor layer 131, an active layer 132 configured to emit blue light, and an n-type semiconductor layer 133 that are stacked in a vertical direction (y direction) on the backplane substrate 110. The vertical direction (y direction) may refer to a direction perpendicular to the backplane substrate 110 (i.e., perpendicular to an upper surface of the backplane substrate 110). The n-type semiconductor layer 133 of the first light-emitting section 101 may include quantum dots 1337, and the n-type semiconductor layer 133 of the third light-emitting section 103 may include quantum dots 1338. The second light-emitting section 102 may include a p-type semiconductor layer 131, an active layer 132 configured to emit blue light, and an n-type semiconductor layer 133a that are stacked in the vertical direction (y direction) on the backplane substrate 110. The n-type semiconductor layer 133a of the second light-emitting section 102 may not include quantum dots and in some embodiments, the second light-emitting section 102 may not include nanopores.

Each of the p-type semiconductor layers 131 and the n-type semiconductor layers 133 and 133a may include a Group II-VI or III-V compound semiconductor material. The p-type semiconductor layers 131 and the n-type semiconductor layers 133 and 133a may have a function of providing electrons and holes to the active layers 132. To this end, the p-type semiconductor layers 131 may be doped with a p-type dopant, and the n-type semiconductor layers 133 and 133a may be doped with an n-type dopant. For example, Mg, Zn, Ca, Se, or Ba may be used as the p-type dopant, and Si, Ge, or Sn may be used as the n-type dopant. The p-type semiconductor layers 131 may provide holes to the active layers 132, and the n-type semiconductor layers 133 and 133a may provide electrons to the active layers 132. The p-type semiconductor layers 131 may include a Group II-VI or III-V p-type semiconductor such as p-GaN. The n-type semiconductor layers 133 and 133a may include a Group II-VI or III-V n-type semiconductor such as n-GaN. However, embodiments are not limited thereto. The p-type semiconductor layers 131 and the n-type semiconductor layers 133 and 133a may have a single-layer or multi-layer structure.

The active layers 132 may include a nitride semiconductor. For example, the active layers 132 may include a GaN-based material. In this case, the active layers 132 may include an undoped GaN-based material or a GaN-based material doped with a dopant. For example, the active layers 132 may include InGaN or InAlGaN.

The active layers 132 may have a quantum well structure in which quantum wells are arranged between barriers. Holes and electrons provided from the p-type semiconductor layers 131 and the n-type semiconductor layers 133 and 133a may recombine in the quantum wells of the active layers 132, thereby generating light. The wavelength of light generated in the active layers 132 may be determined by the energy band gap of a material forming the quantum wells in the active layers 132. The active layers 132 may have a single quantum well, or a multi-quantum well (MQW) structure in which a plurality of quantum wells and a plurality of barriers are alternately arranged. The thickness of the active layers 132 or the number of quantum wells in the active layers 132 may be selected by considering the driving voltage and luminous efficiency of the display apparatus 100. When the active layers 132 has a MQW structure, the active layers 132 may include a quantum well structure including, for example, InGaN/GaN. The active layers 132 may be configured to emit blue light.

A p-type electrode 127 may be provided between the backplane substrate 110 and the first light-emitting section 101, a p-type electrode 127 may be provided between the backplane substrate 110 and the second light-emitting section 102, and a p-type electrode 127 may be provided between the backplane substrate 110 and the third light-emitting section 103. The p-type electrodes 127 may be reflective electrodes. The p-type electrodes 127 may be pixel electrodes configured to apply voltage to corresponding light-emitting sections. An n-type electrode 140 may be commonly connected to the first light-emitting section 101, the second light-emitting section 102, and the third light-emitting section 103. That is, the n-type electrode 140 may be a single electrode connected to each of the first light-emitting section 101, the second light-emitting section 102, and the third light-emitting section 103. The n-type electrode 140 may be formed as one layer along upper portions and side walls of the first light-emitting section 101, the second light-emitting section 102, and the third light-emitting section 103. The n-type electrode 140 may be a common electrode (e.g., commonly connected to the first light-emitting section 101, the second light-emitting section 102, and the third light-emitting section 103). In addition, the n-type electrode 140 may be a transparent electrode through which light is output to the outside.

A distributed Bragg reflection layer 135 may surround the side walls of the first light-emitting section 101, the second light-emitting section 102, and the third light-emitting section 103. The distributed Bragg reflection layer 135 may not be provided on upper portions of the n-type semiconductor layers 133 and 133a. The distributed Bragg reflection layer 135 may be provided on the side walls of the first to third light-emitting sections 101 to 103 and between the first to third light-emitting sections 101 to 103.

A first layer 135a and a second layer 135b having different refractive indexes may be alternately stacked multiple times to form the distributed Bragg reflection layer 135. Due to the difference in refractive index, all waves reflected at interfaces of the first and second layers 135a and 135b may interfere with each other. For example, the distributed Bragg reflection layer 135 may have a structure in which layers including two of Si, Si₃N₄, SiO₂, TiO₂, Ta₂O₅, and ZrO₂ are alternately stacked. For example, the distributed Bragg reflection layer 135 may have a structure in which SiO₂ layers and TiO₂ layers are alternately stacked. Light reflectivity may be adjusted by the thicknesses of two layers and the number of stacked pairs of the two layers of the distributed Bragg reflection layer 135.

For example, the distributed Bragg reflection layer 135 may have a structure in which one to ten pairs of the first layer 135a and the second layer 135b are alternately stacked. For example, the distributed Bragg reflection layer 135 may have a structure in which one to seven pairs of the first layer 135a and the second layer 135b are alternately stacked. The distributed Bragg reflection layer 135 may selectively reflect wavelengths of light emitted from the first to third light-emitting sections 101 to 103, and thus, the reflectivity of a desired wavelength of light may be increased or decreased to improve light extraction efficiency. For example, the distributed Bragg reflection layer 135 may have relatively high reflectivity for blue light and relatively low reflectivity for red and green light. The distributed Bragg reflection layer 135 may have a reflectivity of 70% or more for blue light and a reflectivity of 50% or less for red and green light. Alternatively, the distributed Bragg reflection layer 135 may a reflectivity of 70% or more for blue light and a reflectivity of 30% or less for red and green light.

Blue light emitted from the active layer 132 of the first light-emitting section 101 may be reflected inward by the distributed Bragg reflection layer 135, and then, the blue light may be converted into red light by the quantum dots 1337 of the p-type semiconductor layer 131 of the first light-emitting section 101 and may be emitted to the outside. As blue light is reflected inward, the rate of conversion into red light may be increased, and thus, the luminous efficiency of red light may be increased. In the second light-emitting section 102, blue light emitted from the active layer 132 may be reflected by the distributed Bragg reflection layer 135 and emitted upward of the n-type semiconductor layer 133. Blue light emitted from the active layer 132 of the third light-emitting section 103 may be reflected inward by the distributed Bragg reflection layer 135, and then, the blue light may be converted into green light by the quantum dots 1338 of the p-type semiconductor layer 131 of the third light-emitting section 103 and may be emitted to the outside. As blue light is reflected inward, the rate of conversion into green light may be increased, and thus, the luminous efficiency of green light may be increased.

In addition, a bonding layer 120 may be further provided between the backplane substrate 110 and the first light-emitting section 101, a bonding layer 120 may be further provided between the backplane substrate 110 and the second light-emitting section 102, and a bonding layer 120 may be further provided between the backplane substrate 110 and the third light-emitting section 103. The bonding layers 120 are for bonding the light-emitting section array structure 130 to the backplane substrate 110 and may each include one or two layers. Referring to FIG. 1, the bonding layers 120 may include first bonding layers 118 connected to the driving elements 115, and second bonding layers 125 connected to the p-type electrodes 127. The first bonding layers 118 and the second bonding layers 125 may each include Cu. In the current embodiment, the backplane substrate 110 and the light-emitting section array structure 130 may be bonded to each other by a copper to copper (C2C) bonding method. According to the C2C bonding method, copper may be directly connected to copper to decrease the length of wiring and improve power efficiency. An insulating layer 121 may be provided between the second bonding layers 125. The insulating layer 121 may include, for example, SiO₂.

The first light-emitting section 101, the second light-emitting section 102, and the third light-emitting section 103 may each have a rod shape with a nano-sized or micro-sized diameter. For example, each of the first light-emitting section 101, the second light-emitting section 102, and the third light-emitting section 103 may have a diameter D1 in the range of about 0.5 μm to about 2 μm. Here, the diameter D1 may refer to the maximum diameter when the diameters of the first to third light-emitting sections 101 to 103 are not uniform. The first light-emitting section 101, the second light-emitting section 102, and the third light-emitting section 103 may each have a generally uniform diameter in a height direction thereof (y direction). For example, the p-type semiconductor layer 131, the active layer 132, and the n-type semiconductor layer 133 (133a) of each of the first to third light-emitting sections 101 to 103 may have substantially the same diameter. In addition, when a length between a lower surface of the p-type semiconductor layer 131 and an upper surface of the n-type semiconductor layer 133 (133a) is referred to as a height H of the first to third light-emitting sections 101 to 103, the height H may range from about 2 μm to about 7 μm. In addition, the first light-emitting section 101, the second light-emitting section 102, and the third light-emitting section 103 may have, for example, a large aspect ratio of 4 or more. For example, the diameter D1 of the first to third light-emitting sections 101 to 103 may be selected to be about 600 nm, and the height H of the first to third light-emitting sections 101 to 103 may be selected to be about 5 μm. In this case, the aspect ratio of the first to third light-emitting sections 101 to 103 is slightly greater than 8.

Next, the n-type semiconductor layers 133 are further described.

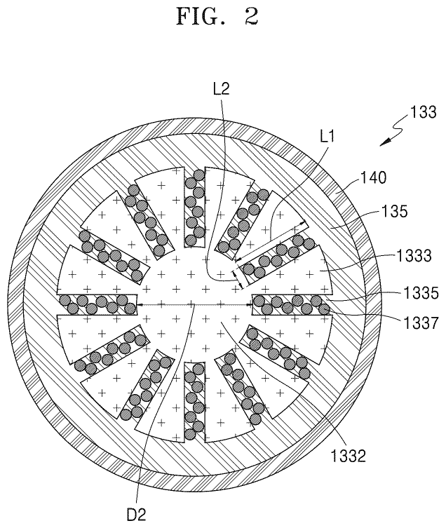

FIG. 2 is a cross-sectional view taken along line A-A′ of FIG. 1 according to an embodiment.

Referring to FIG. 2, the n-type semiconductor layer 133 may include a core rod 1332 and a plurality of nanopores 1335 that are open outward from the core rod 1332. That is, the plurality of nanopores 1335 may have an open end along a sidewall of a respective section and may extend radially outward from the core rod 1332. Furthermore, the n-type semiconductor layer 133 may include a plurality of nanopore layers arranged in the y-direction (i.e., the direction perpendicular to an upper surface of the backplane substrate 110). Each of the plurality of nanopore layers may include a plurality of nanopores 1335, and the nanopores 1335 of each layer may be substantially aligned vertically. The core rod 1332 may be a center region of the n-type semiconductor layer 133 in which the nanopores 1335 are not formed. The first light-emitting section 101, the second light-emitting section 102, and the third light-emitting section 103 may have a cylindrical structure. However, the first light-emitting section 101, the second light-emitting section 102, and the third light-emitting section 103 are not limited thereto and may have various rod structures such as a tetragonal rod structure, a pentagonal rod structure, or a hexagonal rod structure. The n-type semiconductor layer 133 may have a relatively large height compared to the active layer 132 or the p-type semiconductor layer 131. The height H of the n-type semiconductor layer 133 may be greater than the diameter D1 of the n-type semiconductor layer 133.

The diameter D2 of the core rod 1332 may be about ⅕ to about ⅓ of the diameter D1 of the first light-emitting section 101 or the third light-emitting section 103. For example, the diameter D2 of the core rod 1332 may be in a range of about 120 nm to about 200 nm. The diameter D2 of the core rod 1332 may refer to the maximum diameter of the core rod 1332 in any horizontal cross-section of the n-type semiconductor layer 133. The term “horizontal cross-section” may refer to a section taken in a diameter direction (x direction) of the first light-emitting section 101, and the term “vertical cross-section” may refer to a cross-section taken in the height direction (y direction) of the first light-emitting section 101. FIG. 2 illustrates that the core rod 1332 has a roughly circular horizontal cross-section. However, the horizontal cross-section of the core rod 1332 may not be perfectly circular and may be elliptical or irregular. In this case, the diameter D2 of the core rod 1332 may refer to the distance between the nanopores 1335 facing each other across the horizontal cross-section of the core rod 1332 and may be the maximum diameter of the horizontal cross-section of the core rod 1332.

The core rod 1332 ensures a region having a predetermined diameter and thus functions as a passage through which current supplied to the first light-emitting section 101 or the third light-emitting section 103 flows efficiently, thereby increasing electrical stability. In addition, because the core rod 1332 is provided in a center region of each of the first light-emitting section 101 and the third light-emitting section 103, structural stability may be guaranteed.

Referring to FIG. 2, the nanopores 1335 are open and extend radially outward from the core rod 1332. The nanopores 1335 may be arranged radially from the core rod 1332 in the horizontal cross-section of the n-type semiconductor layer 133. The nanopores 1335 may be arranged in an outer region of the n-type semiconductor layer 133 around the core rod 1332. In addition, each of the nanopores 1335 may be shaped such that the length L1 of the nanopore 1335 in the radial direction of the n-type semiconductor layer 133 may be greater than the length L2 of the nanopore 1335 in a direction perpendicular to the radial direction. Referring back to FIG. 1, in a vertical cross-section of the n-type semiconductor layer 133, the nanopores 1335 may be arranged apart from each other in a line in the height direction or vertical direction (y direction) of the n-type semiconductor layer 133. That is, the nanopores 1335 may be substantially aligned in the y direction with each other. In other words, the nanopores 1335 in a first nanopore layer may be vertically aligned with nanopores 1335 of other nanopore layers.

The quantum dots 1337 are dispersed in the nanopores 1335. The quantum dots 1337 may be inorganic materials with a size of several nanometers (nm). The quantum dots 1337 may have an energy bandgap corresponding to a specific wavelength, and when the quantum dots 1337 absorb light having energy greater than the energy bandgap, the quantum dots 1337 may emit light of a different wavelength, thereby performing color conversion. The quantum dots 1337 have a narrow emission wavelength band and may thus enhance the color reproducibility of the display apparatus 100.

The quantum dots 1337 may have a core-shell structure with a core and a shell, or a particle structure without a shell. The core-shell structure may be a single-shell structure or a multi-shell structure such as a double-shell structure.

The quantum dots 1337 may include a Group II-VI semiconductor, a Group III-V semiconductor, a Group IV-VI semiconductor, a Group IV semiconductor, and/or graphene quantum dots. For example, the quantum dots 1337 may include Cd, Se, Zn, S, and/or InP, and each of the quantum dots 1337 may have a diameter of several tens of nanometers (nm) or less, for example, about 10 nm or less. The quantum dots 1337 may include a compound such as CdSe, CdTe, InP, InAs, InSb, PbSe, PbS, PbTe, AlAs, ZnS, ZnSe, ZnTe, or graphene. The quantum dots 1337 may absorb light in a specific wavelength band and emit light in a longer wavelength band. The wavelength of light that the quantum dots 1337 absorb may vary depending on the energy bandgap of the quantum dots 1337. The energy bandgap of the quantum dots 1337 may vary depending on the material or size of the quantum dots 1337. For example, the quantum dots 1337 of the first light-emitting section 101 may convert blue light emitted from the active layer 132 into red light. In addition, the quantum dots 1338 of the third light-emitting section 103 may convert blue light emitted from the active layer 132 into green light.

When the active layer 132 includes indium (In), the wavelength of light emitted from the active layer 132 may increase as the indium content of the active layer 132 increases. For example, when the indium content of the active layer 132 is about 15%, the active layer 132 may emit blue light having a wavelength of about 450 nm. However, the composition of the active layer 132 is not limited thereto and may be implemented in various manners.

When the first light-emitting section 101 and the third light-emitting section 103 have very small sizes in a nano or micro range, the external quantum efficiency (EQE) and internal quantum efficiency (IQE) of the active layer 132 may decrease as the emission wavelength of the first light-emitting section 101 and the third light-emitting section 103 increases. In addition, as the indium content of the active layer 132 increases, defects caused by lattice mismatch may increase. Therefore, the active layer 132 is configured to generate light in a relatively short wavelength band with high luminous efficiency, and the quantum dots 1337 and 1338 are configured to convert light of a relatively short wavelength into light of a relatively long wavelength, thereby improving the luminous efficiency of the first light-emitting section 101 and the third light-emitting section 103.

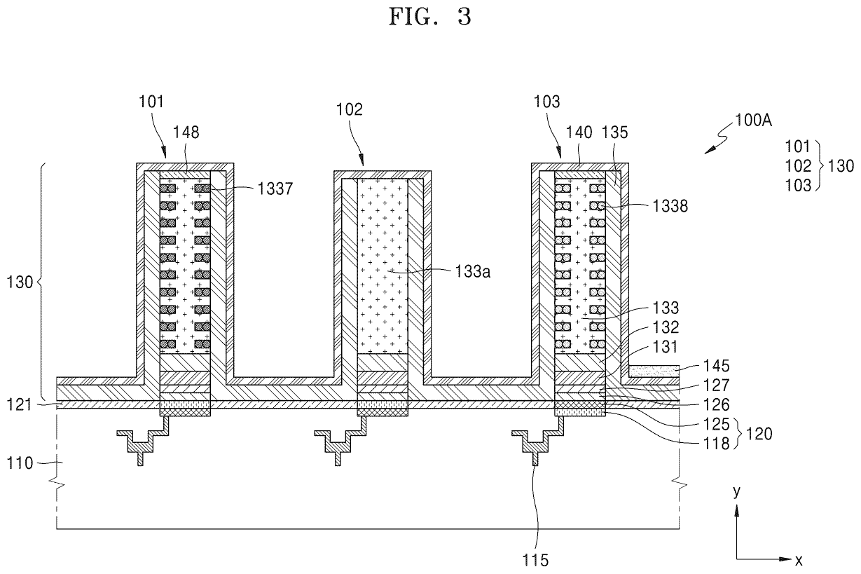

FIG. 3 is a cross-sectional view illustrating an example in which the display apparatus shown in FIG. 1 further includes reflection layers and etching barriers according to an embodiment. That is, FIG. 3 illustrates an example in which the display apparatus 100 shown in FIG. 1 further includes etching barriers 126 and reflection layers 148. In FIG. 3, elements denoted with the same reference numerals as those in FIG. 1 have substantially the same structures and operational effects as those in FIG. 1, and thus, detailed descriptions thereof may be omitted here.

In a display apparatus 100A, the etching barriers 126 may be provided between bonding layers 120 and p-type electrodes 127. The etching barriers 126 may include indium tin oxide (ITO). The etching barriers 126 may include a material having etching selectivity to control etching regions during a manufacturing process. In addition, the reflection layers 148 may be further provided on upper surfaces of n-type semiconductor layers 133 of a first light-emitting section 101 and a third light-emitting section 103. The reflection layers 148 may include, for example, aluminum (Al) or silver (Ag). Blue light emitted from active layers 132 may be reflected inward back into the active layers 132, thereby increasing the utilization of blue light and improving the luminous efficiency of red and green light. There is no reflection layer on a second light-emitting section 102, and thus, blue light generated in the second light-emitting section 102 may be emitted to the outside.

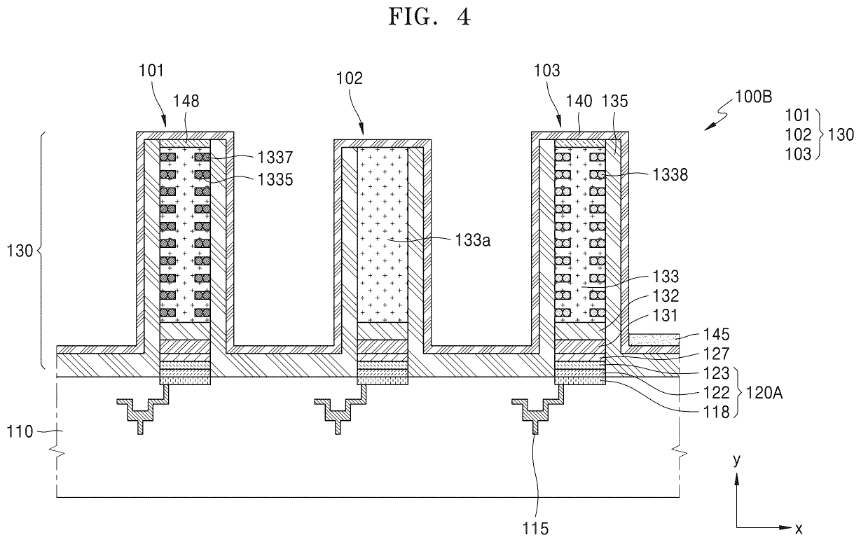

FIG. 4 is a cross-sectional view illustrating an example in which boding layers of the display apparatus shown in FIG. 1 are modified according to an embodiment.

In a display apparatus 100B, bonding layers 120A may each include a first bonding layer 118, a second bonding layer 122, and a third bonding layer 123. The first bonding layer 118 may include copper. The second bonding layer 122 and the third bonding layer 123 may include a eutectic bonding material. The first bonding layer 118 may be embedded in a backplane substrate 110, and the second bonding layer 122 and the third bonding layer 123 may be provided on the backplane substrate 110. A backplane substrate 110 and a light-emitting section array structure 130 may be bonded to each other by a eutectic bonding method using the second bonding layer 122 and the third bonding layer 123.

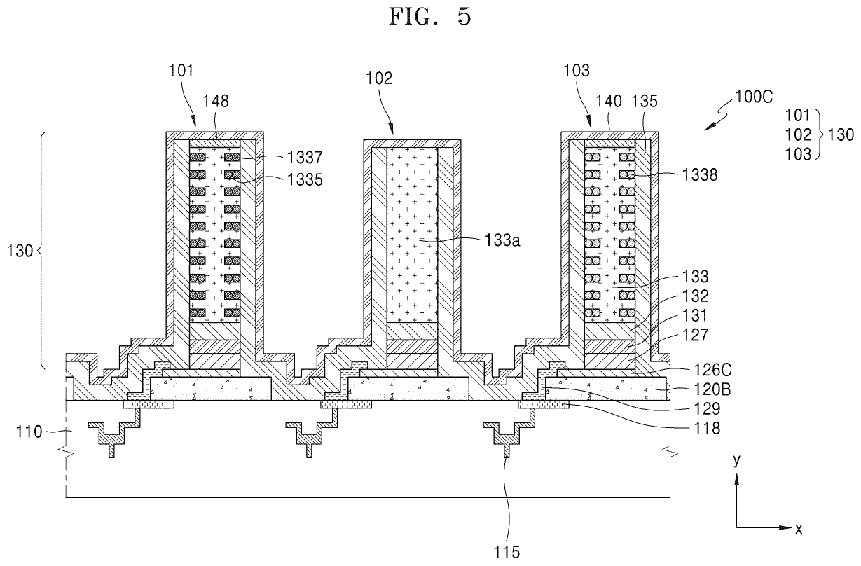

FIG. 5 is a cross-sectional view illustrating an example in which the bonding layers of the display apparatus shown in FIG. 1 are modified according to an embodiment.

A display apparatus 100C may include bonding layers 120B provided between a backplane substrate 110 and p-type electrodes 126C. The bonding layers 120B may be adhesive bonding layers. The bonding layers 120B may include, for example, benzocyclobutene (BCB). The bonding layers 120B may be arranged apart from each other and may respectively corresponding to a first light-emitting section 101, a second light-emitting section 102, and a third light-emitting section 103. The bonding layers 120B include an insulating material, and thus, wiring 129 may be provided to electrically connect the p-type electrodes 126C and driving elements 115 to each other. The wiring 129 may be electrically connected to the driving elements 115 through first bonding layers 118 that include copper. In one or more embodiments, the first bonding layers 118 do not contribute to the bonding of the backplane substrate 110 and a light-emitting section array structure 130 to each other, and the backplane substrate 110 and the light-emitting section array structure 130 may be bonded to each other by the bonding layers 120B.

In each of the display apparatuses 100, 100A, 100B, and 100C, the nanopores 1335 extend radially outward in the n-type semiconductor layers 133, and the core rods 1332 are provided in the n-type semiconductor layers 133. The core rods 1332 may serve as passages such that current supplied to the first and third light-emitting sections 101 and 103 having a rod shape may flow through the core rods 1332, and thus, electrical stability may be secured. In addition, because the core rods 1332 are provided in center portions of the n-type semiconductor layers 133, structural stability may be secured. In addition, the wavelength of light emitted from the active layers 132 may be converted by the quantum dots 1337 and 1338 embedded in the nanopores 1335, thereby guaranteeing an EQE of 10% or more.

For example, an AlGaInP red light-emitting diode (LED) not including quantum dots may have high luminous efficiency when the size of the AlGaInP red LED is 100 μm×100 μm or more, but the luminous efficiency of the AlGaInP red LED sharply decreases as the size of the AlGaInP red LED decreases. The EQE of the AlGaInP red LED not including quantum dots may be less than 0.5%. Thus, the efficiency of an InGaN red LED not including quantum dots is relatively less affected by the size of the InGaN red LED compared to the AlGaInP red LED not including quantum dots. However, due to defects resulting from lattice mismatch caused by a high indium content of about 35% for a wavelength of 630 nm, the InGaN red LED not including quantum dots may have a low IQE of 20% or less and a low EQE of 5%. However, according to embodiments, the EQE of a rod-shaped light-emitting section may be 10% or more even when the rod-shaped light-emitting section is nano-sized.

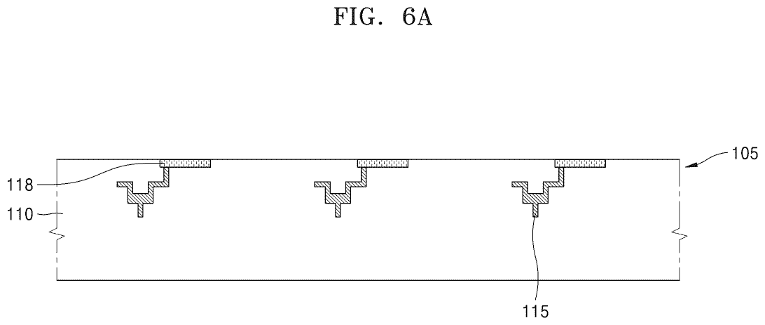

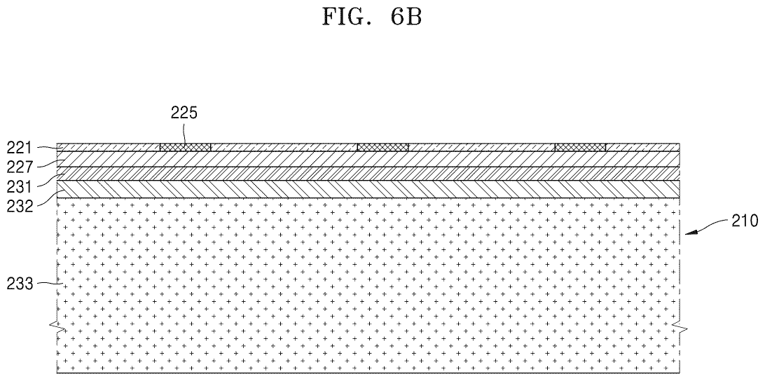

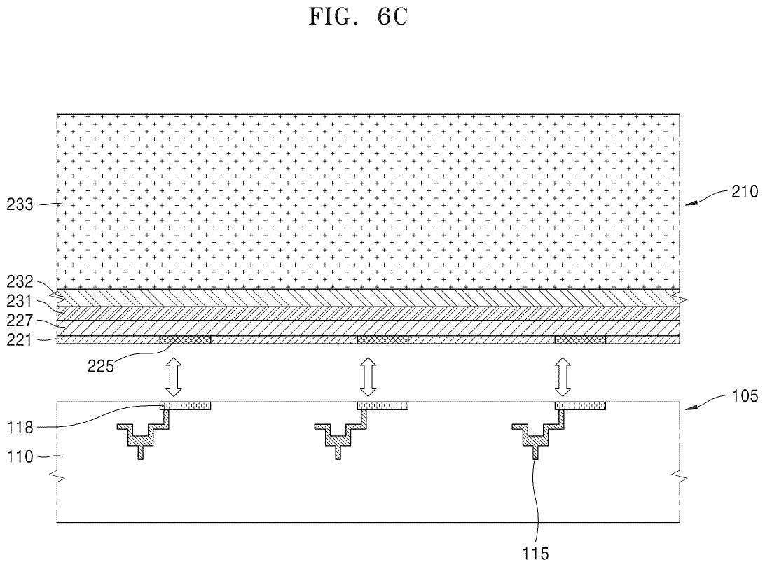

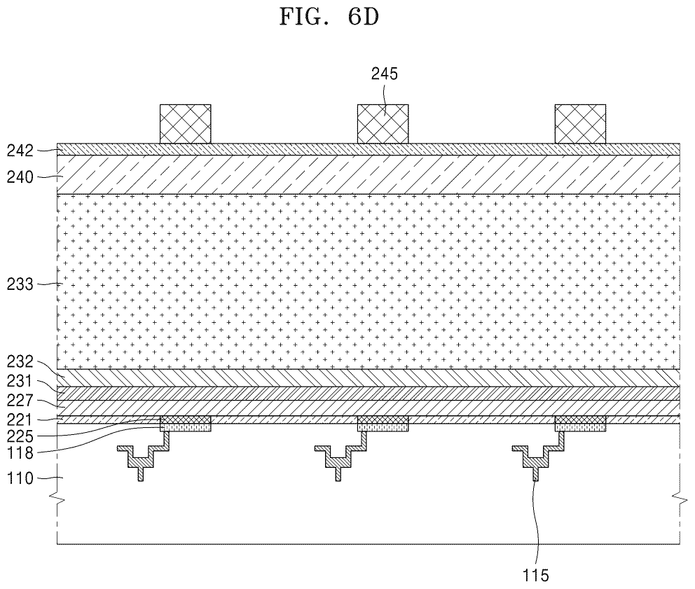

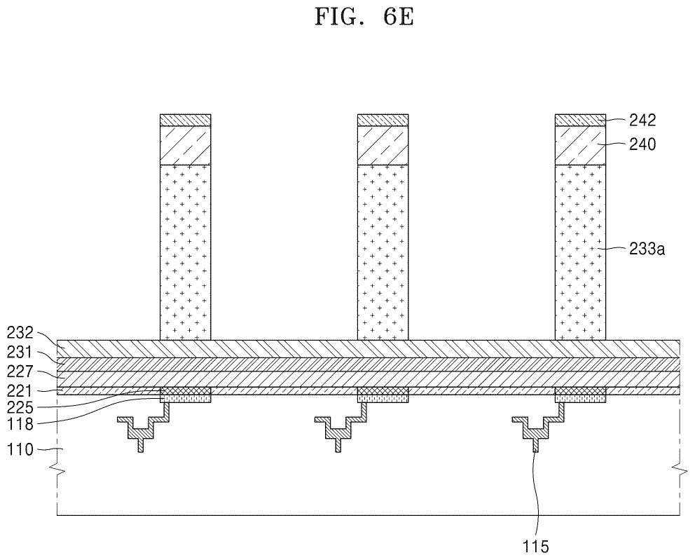

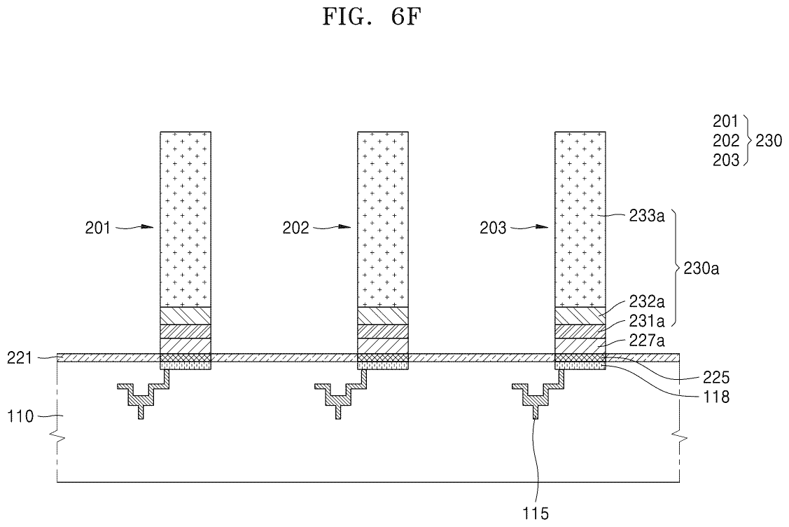

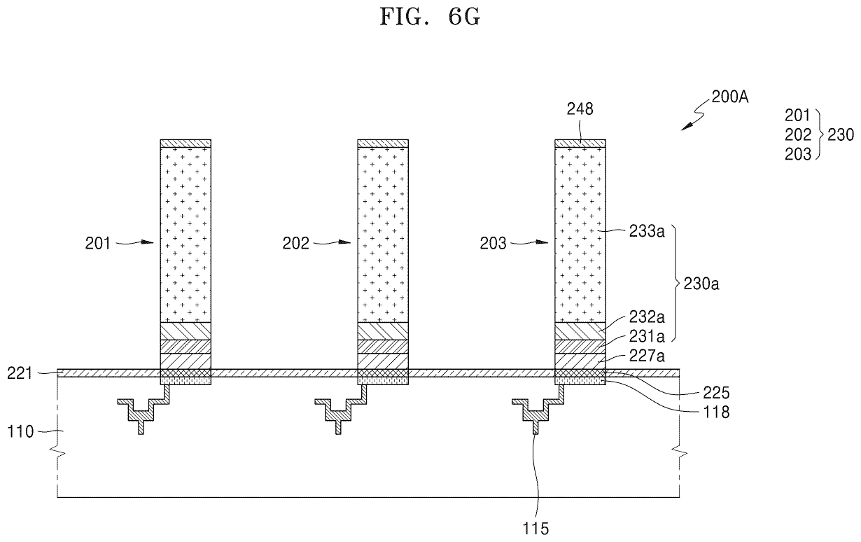

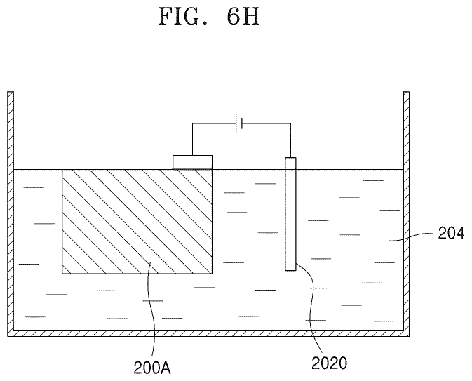

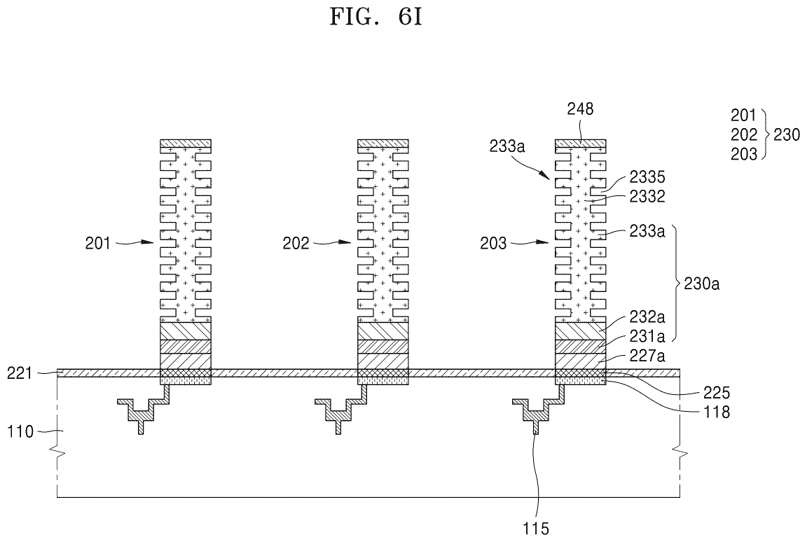

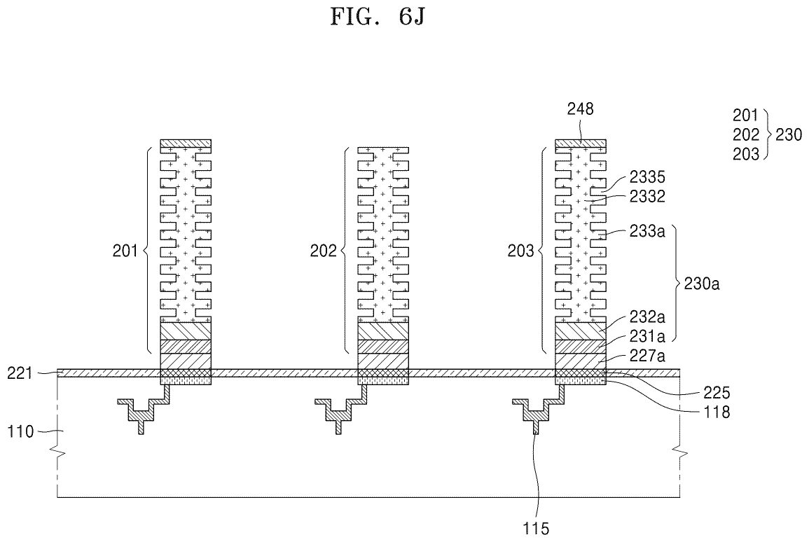

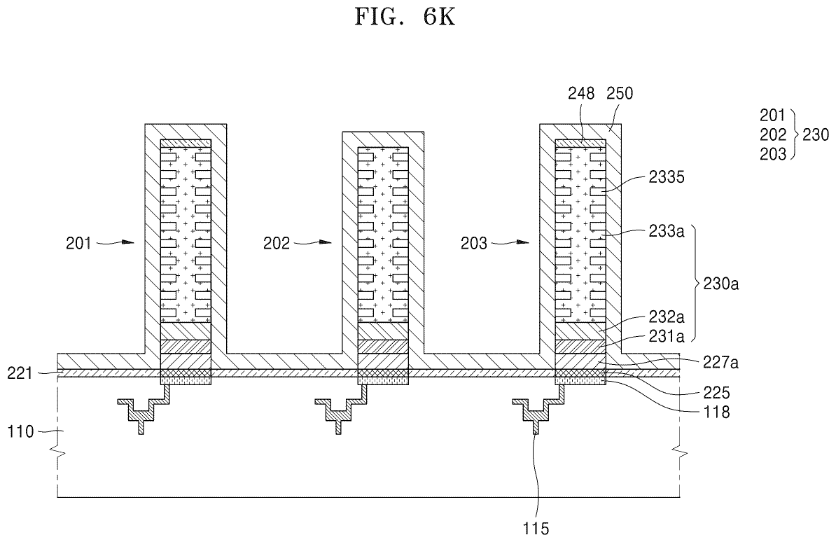

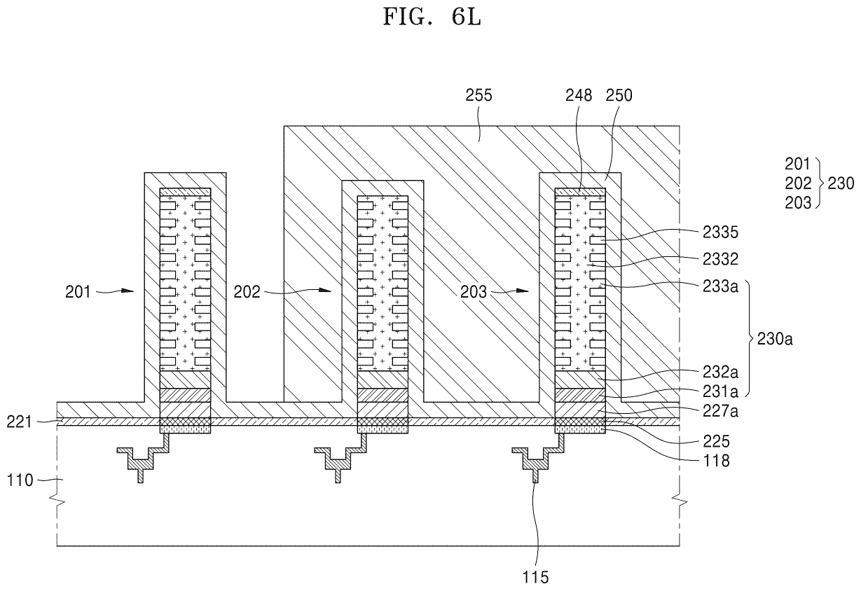

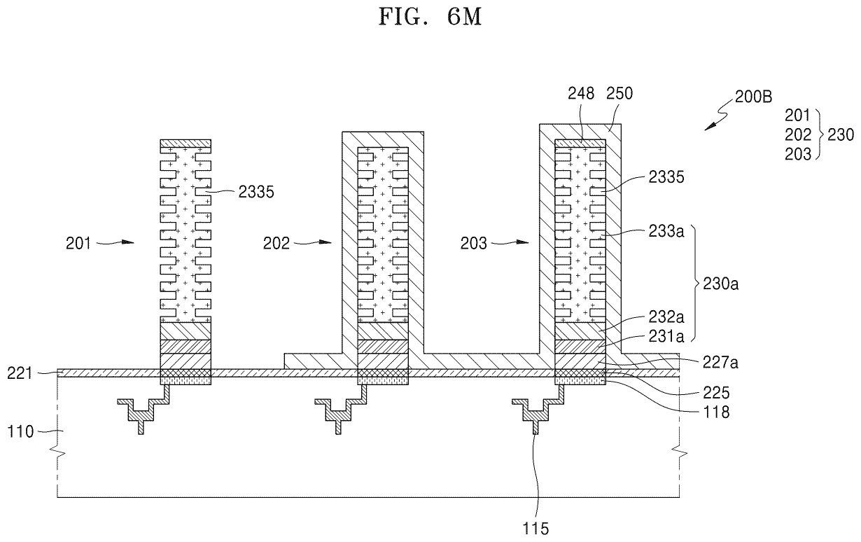

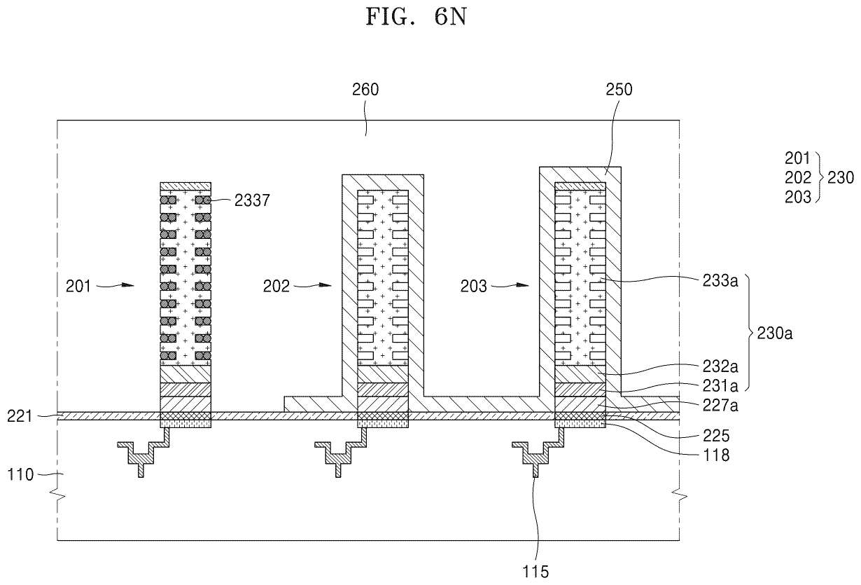

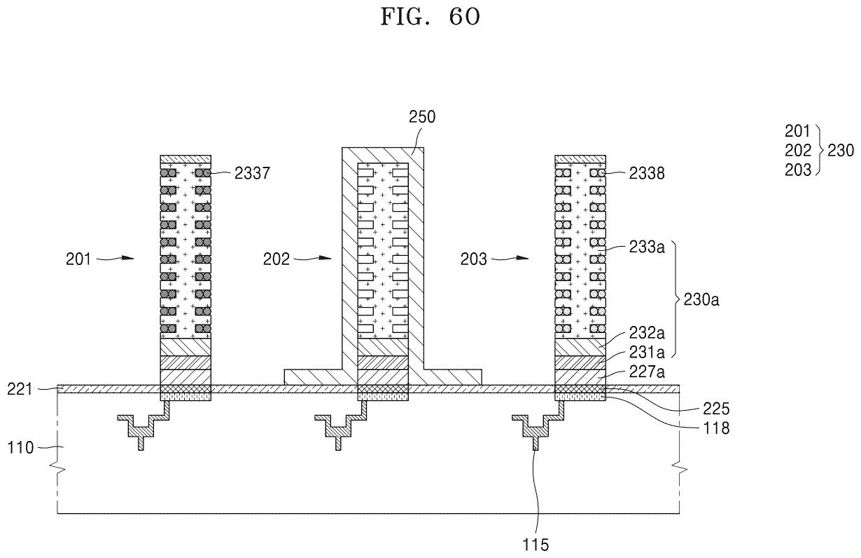

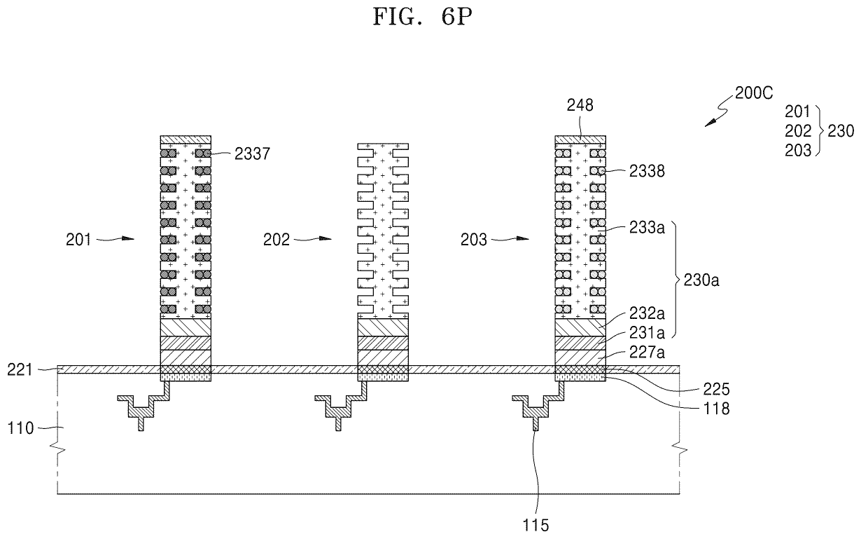

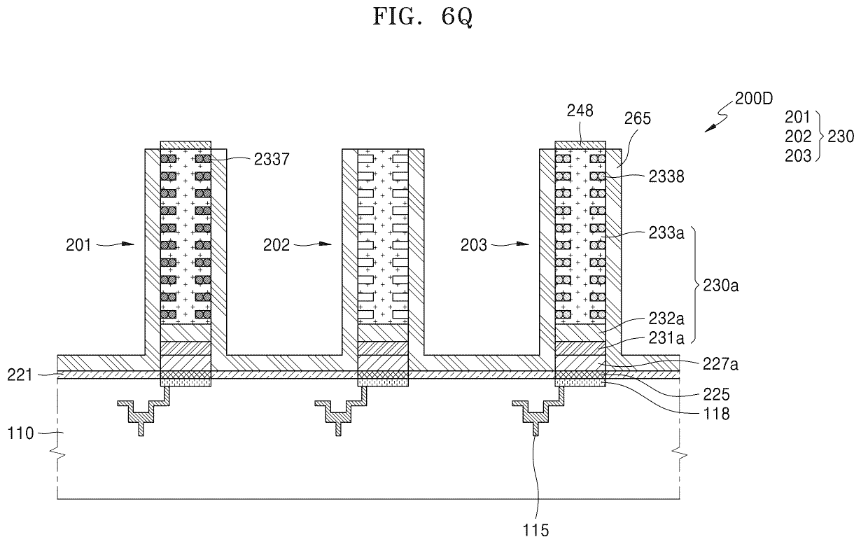

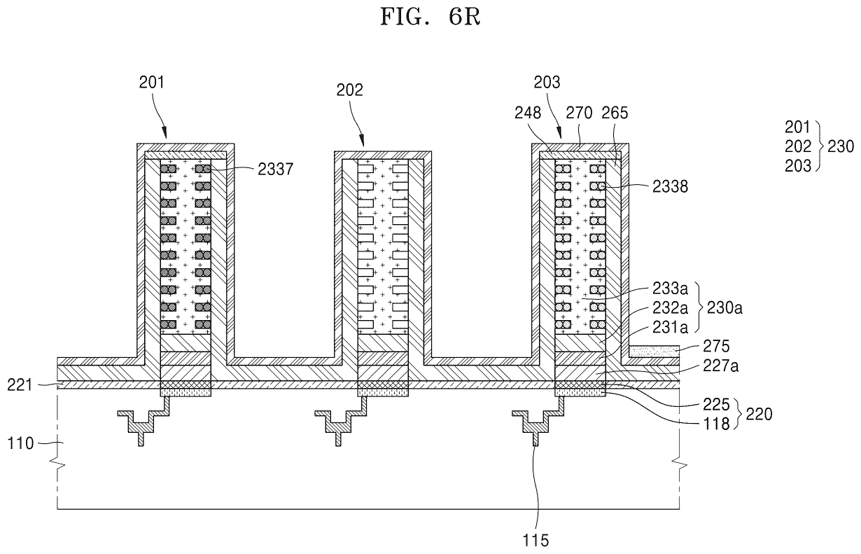

Hereinafter, a method of manufacturing a display apparatus is described according to an embodiment with reference to FIGS. 6A to 6R.

FIGS. 6A to 6R are diagrams illustrating a method of manufacturing a display apparatus according to an embodiment.

Referring to FIG. 6A, driving elements 115 are formed on a backplane substrate 110, an upper surface of the backplane substrate 110 is patterned and etched, and then, first bonding layers 118 are formed in etched regions. The structure shown in FIG. 6A may be referred to as a backplane structure 105.

Referring to FIG. 6B, an active layer 232 and a p-type semiconductor layer 231 are sequentially deposited on an n-type semiconductor layer 233. The n-type semiconductor layer 233 may include, for example, n-type GaN. The active layer 232 may have a single quantum well structure or a multi-quantum well structure. The active layer 232 may include InGaN or InAlGaN. The p-type semiconductor layer 231 may include, for example, p-type GaN. However, embodiments are not limited thereto. A p-type electrode layer 227 is deposited on the p-type semiconductor layer 231, and an insulating layer is deposited on the p-type electrode layer 227. The insulating layer is patterned and etched, and then, second bonding layers 225 are formed in etched regions. A stacked structure 210 formed as described above may be a structure for forming light-emitting sections.

Referring to FIG. 6C, the stacked structure 210 may be flipped and placed onto the backplane to bring the first bonding layers 118 and the second bonding layers 225 into contact with each other, and then the first bonding layers 118 and the second bonding layers 225 may be bonded to each other by heat treatment, thereby bonding the backplane structure 105 and the stacked structure 210 to each other. The backplane structure 105 and the stacked structure 210 may be bonded to each other by a C2C bonding method. Although the C2C bonding method is described as an example, a eutectic bonding method may be used to bond the backplane structure 105 and the stacked structure 210 to each other.

Referring to FIG. 6D, a first hard mask 240 and a second hard mask 242 may be formed on the n-type semiconductor layer 233. Thereafter, a soft mask 245 may be formed on the second hard mask 242. The soft mask 245 may include photoresist. For example, a photoresist layer may be formed on the second hard mask 242, and the photoresist layer may be patterned through a lithography process to form the soft mask 245. Thereafter, portions of an upper surface of the second hard mask 242 are exposed between adjacent nano-patterns of the soft mask 245.

The first hard mask 240 may include an oxide mask material having high selectivity to a semiconductor material of the p-type semiconductor layer 231 and the n-type semiconductor layer 233. The thickness of the first hard mask 240 may be about ⅕ to about 1/10 of a thickness from the n-type semiconductor layer 233 to the p-type semiconductor layer 231. For example, the first hard mask 240 may have a thickness of about 200 nm to about 2 μm. The second hard mask 242 may include a metal mask material having high selectivity to a material of the first hard mask 240. The thickness of the second hard mask 242 may be about ⅕ to about ⅛ of the thickness of the first hard mask 240. For example, the second hard mask 242 may have a thickness of about 25 nm to about 400 nm by considering selectivity to the first hard mask 240 and thickness of the first hard mask 240. For example, the first hard mask 240 may include SiO₂, and the second hard mask 242 may include chromium (Cr), aluminum (Al), tungsten (W), titanium (Ti), silver (Ag), or gold (Au).

Referring to FIG. 6E, the second hard mask 242 exposed between the adjacent nano-patterns of the soft mask 245 may be etched. The etching of the second hard mask 242 may be performed, for example, by a dry etching method using a chlorine-based gas as an etching gas and inductive coupled plasma (ICP) equipment or reactive ion etching (RIE) equipment. The second hard mask 242 may be patterned like two-dimensionally arrayed circular dots, portions of the first hard mask 240 may be exposed between adjacent patterns of the second hard mask 242, and the first hard mask 240 may be etched. The etching of the first hard mask 240 may be performed, for example, by a dry etching method using a fluorine-based gas or argon (Ar) gas as an etching gas and ICP or RIE equipment. For example, a mixture of CF₄ and CHF₃ gases, a mixture of CF₃ and Ar gases, or Ar gas alone may be used as the etching gas. The n-type semiconductor layer 233 may be etched using the first hard mask 240 to form n-type semiconductor layers 233a of sub-pixels. Reference number 233a refers to a rod-shaped n-type semiconductor layer provided in each sub-pixel.

Referring to FIG. 6F, the active layer 232 and the p-type semiconductor layer 231 may be partially dry-etched using the first hard mask 240 to form active layers 232a and p-type semiconductor layers 231a of the sub-pixels. Light-emitting sections 230a of the sub-pixels include the p-type semiconductor layers 231a, the active layer 232a, and the n-type semiconductor layers 233a that have a nano-sized diameter. Thereafter, the p-type electrode layer 227 may be etched to form p-type electrodes 227a. For example, the etching of the p-type electrode layer 227 may be performed using a chlorine-based gas as an etching gas while supplying hydrogen (H₂), nitrogen (N₂), argon (Ar), or a mixture of these gases to a chamber as a plasma ignition and activator. The etching may be performed until the insulating layer is exposed.

Thereafter, the remainder of the first hard mask 240 and the second hard mask 242 may be removed. Then, a light-emitting section array structure 230 may be formed at once on the backplane substrate 110. The light-emitting section array structure 230 may include a first light-emitting section 201 that emits red light, a second light-emitting section 202 that emits blue light, and a third light-emitting section 203 that emits green light. After the dry etching, the diameters of the light-emitting sections 230a may be made more uniform in the height direction of the light-emitting sections 230a through wet treatment using, for example, a KOH solution or a tetramethyl ammonium hydroxide (TMAH) solution.

Referring to FIG. 6G, reflection layers 248 may be deposited on the n-type semiconductor layers 233a. The reflection layers 248 may include, for example, aluminum (Al) or silver (Ag).

Next, FIG. 6H schematically illustrates an electrochemical etching apparatus.

A structure 200A shown in FIG. 6G may be immersed in an electrolyte solution 204. For example, an oxalic acid solution or a sodium nitrate (NaNO₃) solution may be used as the electrolyte solution 204. Thereafter, a positive voltage may be applied to the structure 200A, and a negative voltage may be applied to the electrolyte solution 204. A negative electrode 2020 may be immersed in the electrolyte solution 204. The negative electrode 2020 may include, for example, platinum (Pt).

An electrochemical etching method may perform by immersing a sample to be etched in a specific solvent and connecting electrodes respectively to the sample and the solvent to generate carriers by an external bias. In the electrochemical etching method, the electrode may be directly connected to the sample or indirectly connected to the sample using two chambers.

When a voltage is applied to the structure 200A through an electrode connected to the structure 200A, the n-type semiconductor layers 233a may be selectively etched under specific conditions. Voltage may be selectively applied to etch lateral portions of the n-type semiconductor layers 233a in which carriers are easily confined. The depth of etching may be controlled by etching time and voltage. For example, a voltage of about 10 V to 20 V may be applied for a time period of about 5 minutes to about 20 minutes. For example, an etchant including at least one selected from KOH, NaOH, HCl, C₂H₂O₄, H₂SO₄, HNO₃, and HF may be used.

Referring to FIG. 61, as the n-type semiconductor layers 233a are selectively etched by the electrochemical etching method, nanopores 2335 may be formed in the n-type semiconductor layers 233a, and core rods 2332 may be formed in center portions of the n-type semiconductor layers 233a. In some embodiments, nanopores are not formed in the second light-emitting section 202.

Referring to FIG. 6J, the reflection layer 248 formed on the n-type semiconductor layer 233a of the second light-emitting section 202 is removed. The reflection layer 248 having high reflectivity for blue light may be removed for the second light-emitting section 202 to emit blue light.

Referring to FIG. 6K, a quantum dot patterning layer 250 is formed on an outer surface of the light-emitting section array structure 230 and the insulating layer. The quantum dot patterning layer 250 may include a material that is removable using a wet etchant. For example, the quantum dot patterning layer 250 may include SiO₂. The quantum dot patterning layer 250 may be a layer to be patterned for selectively injecting quantum dots into the nanopores 2335 of the light-emitting sections 230a.

Referring to FIG. 6L, the second light-emitting section 202 and the third light-emitting section 203 are covered with a photoresist 255, but the first light-emitting section 201 is not covered with the photoresist 255. This is to form quantum dots in the first light-emitting section 201. In this state, the quantum dot patterning layer 250 that covers the first light-emitting section 201 may be removed using a wet etchant. The second light-emitting section 202 and the third light-emitting section 203 that are covered with the photoresist 255 are not affected by the wet etchant.

Referring to FIG. 6M, the quantum dot patterning layer 250 is removed from the first light-emitting section 201, and then, the photoresist 255 is removed. Then, the nanopores 2335 of the n-type semiconductor layer 233a of the first light-emitting section 201 are exposed, and the nanopores 2335 of the second light-emitting section 202 and the third light-emitting section 203 may be shielded by the quantum dot patterning layer 250.

Referring to FIG. 6N, a structure 200B shown in FIG. 6M is immersed in a liquid 260 containing quantum dots. Then, as shown in FIG. 6N, quantum dots 2337 may be filled in the nanopores 2335 of the first light-emitting section 201. For example, the quantum dots 2337 may convert blue light into red light. The operation of filling the nanopores 2335 with the quantum dots 2337 may include a dipping operation or a spin coating operation. The quantum dots 2337 may have a diameter in a range of about 5 nm to about 7 nm. The quantum dots 2337 embedded in the nanopores 2335 may increase scattering of light entering the n-type semiconductor layer 233a, thereby improve color conversion efficiency.

Referring to FIG. 6O, quantum dots 2338 may be formed in the nanopores 2335 of the third light-emitting section 203. For example, to form the quantum dots 2338, the first light-emitting section 201 and the second light-emitting section 202 are covered with a photoresist by the method described with reference to FIG. 6I, but the third light-emitting section 203 is not covered with the photoresist. Thereafter, the quantum dot patterning layer 250 covering the third light-emitting section 203 may be removed using a wet etchant. Then, the nanopores 2335 of the third light-emitting section 203 may be opened. After removing the photoresist covering the first light-emitting section 201 and the second light-emitting section 202, the structure 200B is immersed in the liquid 260 containing quantum dots as described with reference to FIG. 6N. As a result, the quantum dots 2338 may be filled in the nanopores 2335 of the third light-emitting section 203 as shown in FIG. 6O. For example, the quantum dots 2338 may convert blue light into green light.

Referring to FIG. 6P, the quantum dot patterning layer 250 remaining on the second light-emitting section 202 is removed.

Referring to FIG. 6Q, a distributed Bragg reflection layer 265 is formed on a structure 200C shown in FIG. 6P. The distributed Bragg reflection layer 265 may be formed by alternately stacking two layers with different refractive indexes several times. A mask pattern may be used such that the distributed Bragg reflection layer 265 may not be formed on upper surfaces of the first light-emitting section 201, the second light-emitting section 202, and the third light-emitting section 203. Alternatively, the distributed Bragg reflection layer 265 may be formed to entirely cover the first light-emitting section 201, the second light-emitting section 202, and the third light-emitting section 203, and then, the distributed Bragg reflection layer 265 may be removed from the upper surfaces of the first light-emitting section 201, the second light-emitting section 202, and the third light-emitting section 203.

Referring to FIG. 6R, an n-type electrode layer 270 may be formed on a structure 200D shown in FIG. 6Q. The n-type electrode layer 270 may be a transparent electrode. Thereafter, an electrode pad 275 may be formed on a side of the third light-emitting section 203. The first bonding layers 118 and the second bonding layers 225 may form a bonding layer 220.

In this manner, a display apparatus including the quantum dots 2337 formed in the first light-emitting section 201 and the quantum dots 2338 formed in the third light-emitting section 203 may be manufactured.

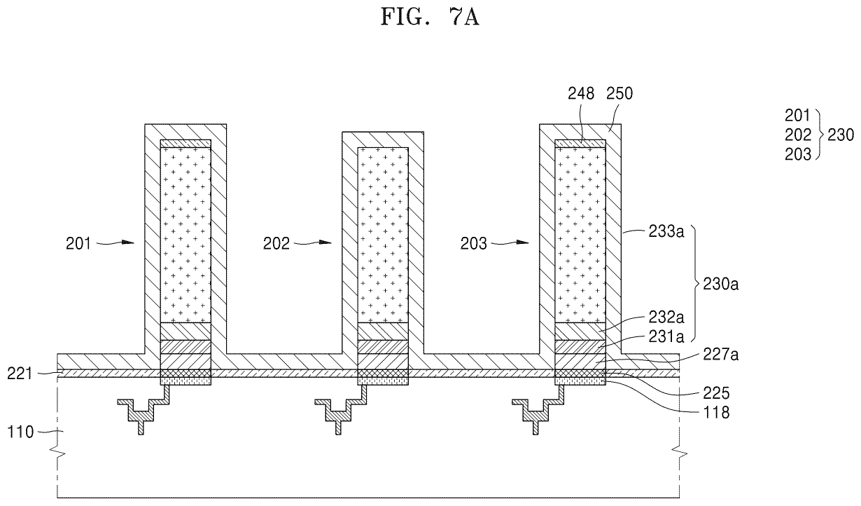

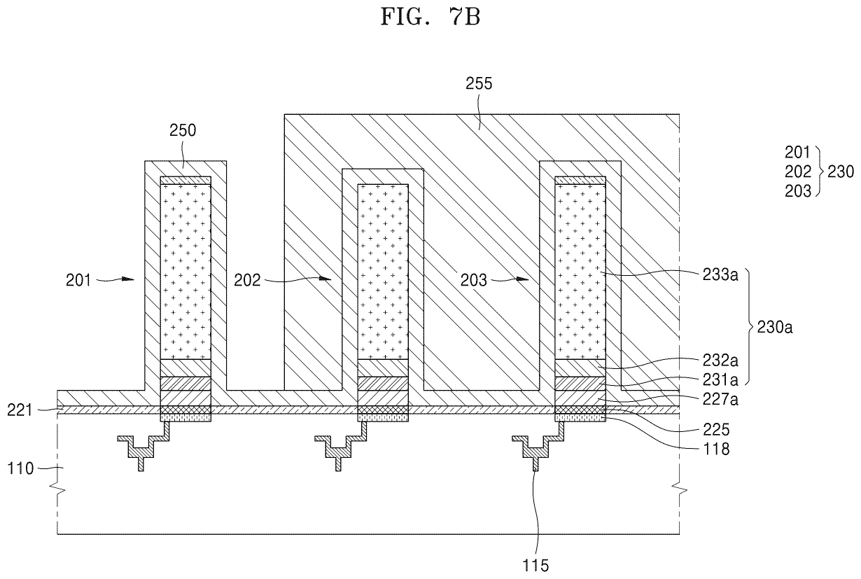

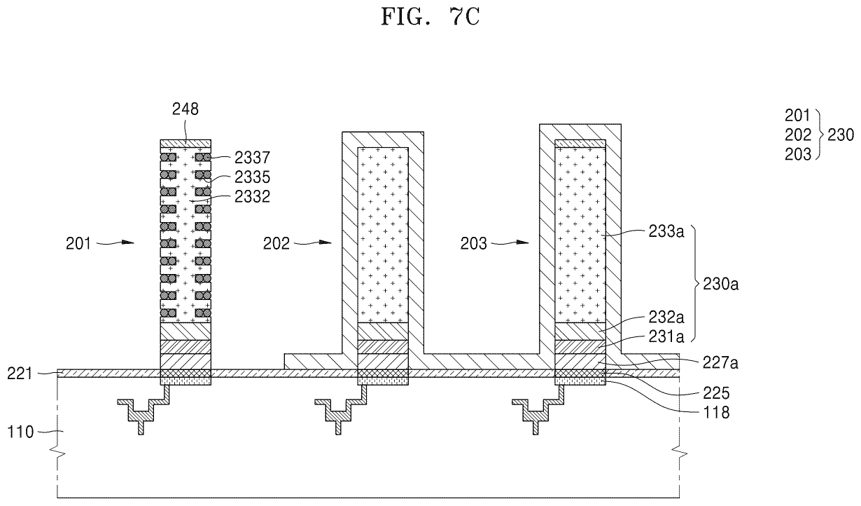

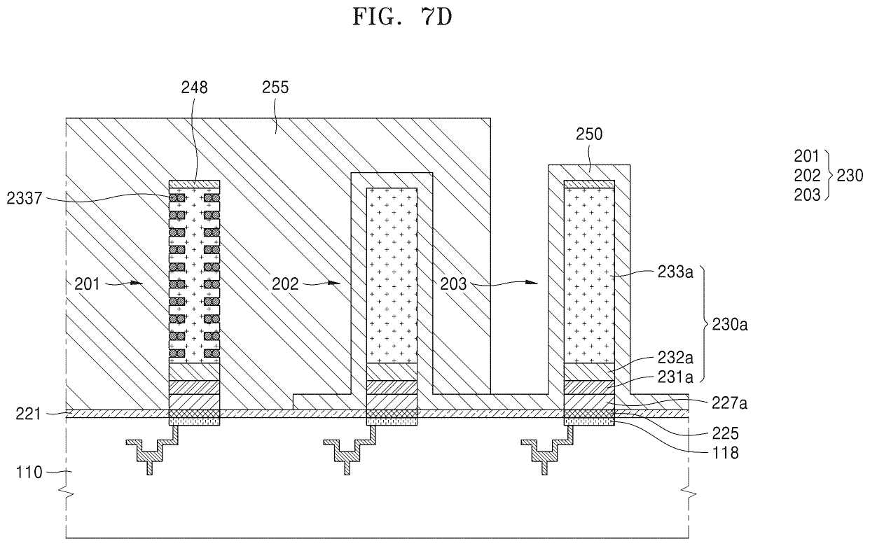

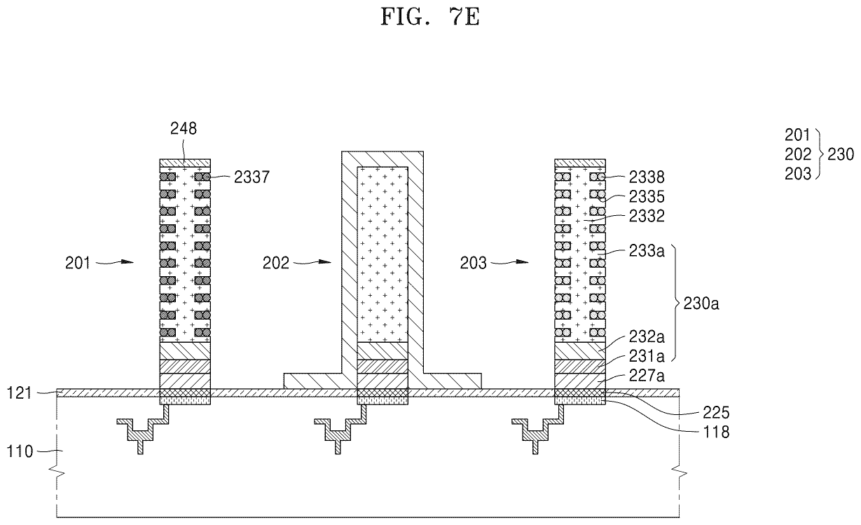

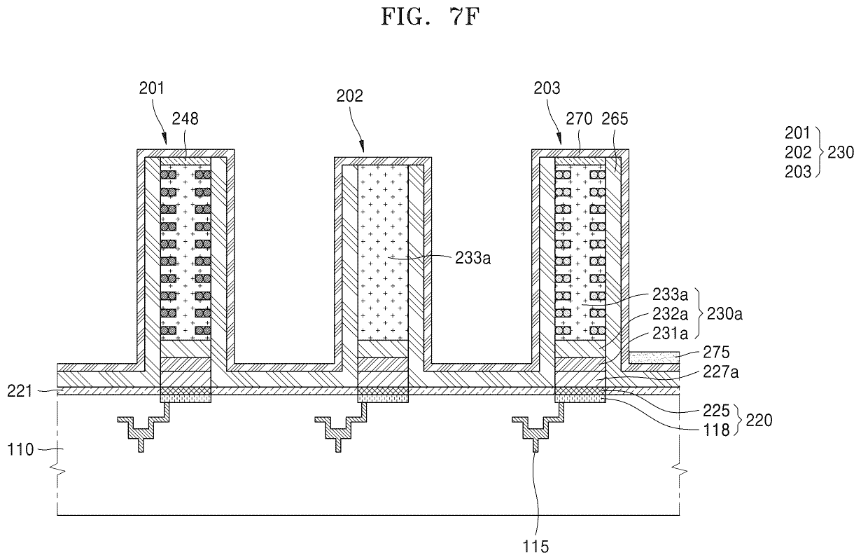

FIGS. 7A to 7F are diagrams illustrating a method of manufacturing a display apparatus according to an embodiment.

A method of manufacturing a display apparatus is described according to another embodiment with reference to FIGS. 7A to 7F. Elements denoted with the same reference numerals as the elements described with reference to FIGS. 6G to 6R may have substantially the same structures as the elements described with reference to FIGS. 6G to 6R and repeated descriptions may be omitted.

Referring to FIG. 7A, in the structure 200A shown in FIG. 6G, the reflection layer 248 formed on the second light-emitting section 202 is removed, and then, a quantum dot patterning layer 250 is formed to cover the first light-emitting section 201, the second light-emitting section 202, and the third light-emitting section 203. Thereafter, referring to FIG. 7B, the second light-emitting section 202 and the third light-emitting section 203 are covered with a photoresist 255, but the first light-emitting section 201 is not covered with the photoresist 255. Thereafter, the quantum dot patterning layer 250 is removed from the first light-emitting section 201 by using a wet etchant. Referring to FIG. 7C, after removing the photoresist 255, nanopores 2335 are formed in the n-type semiconductor layer 233a of the first light-emitting section 201 by using the electrochemical etching apparatus shown in FIG. 6H. Thereafter, a resulting structure including the nanopores 2335 is immersed in a liquid 260 containing quantum dots as shown in FIG. 6N to fill the nanopores 2335 of the first light-emitting section 201 with quantum dots 2337.

Referring to FIG. 7D, the first light-emitting section 201 and the second light-emitting section 202 are covered with a photoresist 255, but the third light-emitting section 203 is not covered with the photoresist 255. Thereafter, the quantum dot patterning layer 250 is removed from the third light-emitting section 203. After removing the photoresist 255, nanopores 2335 are formed in the n-type semiconductor layer 233a of the third light-emitting section 203 by the same method as described with reference to FIG. 7C. Thereafter, a resulting structure including the nanopores 2335 in the third light-emitting section 203 is immersed in the liquid 260 containing quantum dots to fill the nanopores 2335 of the third light-emitting section 203 with quantum dots 2338. Thereafter, the quantum dot patterning layer 250 remaining on the second light-emitting section 202 is removed.

Referring to FIG. 7F, a distributed Bragg reflection layer 265, an n-type electrode layer 270, and an electrode pad 275 may be formed on the structure shown in FIG. 7E. The distributed Bragg reflection layer 265, the n-type electrode layer 270, and the electrode pad 275 may be formed in the same manner as described with reference to FIGS. 6Q and 6R.

In this manner, a display apparatus including the quantum dots 2337 formed in the first light-emitting section 201 and the quantum dots 2338 formed in the third light-emitting section 203 may be manufactured. Furthermore, the second light-emitting section 202 may be manufactured without nanopores.

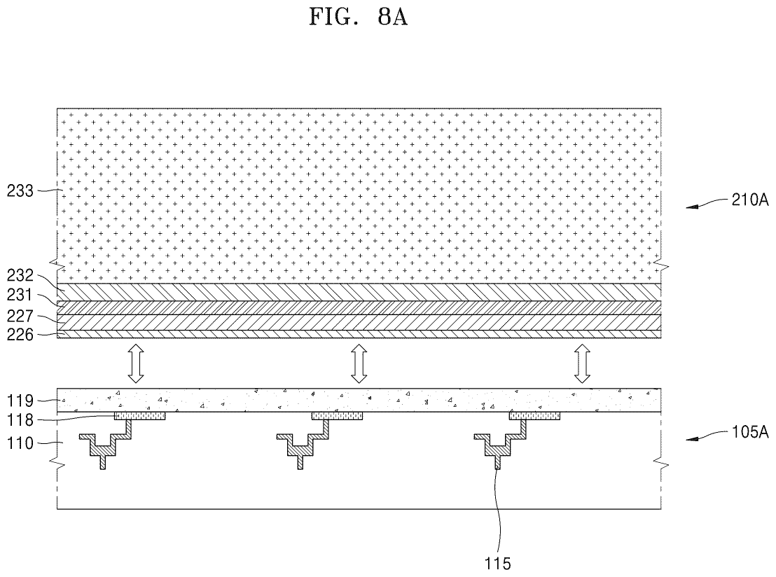

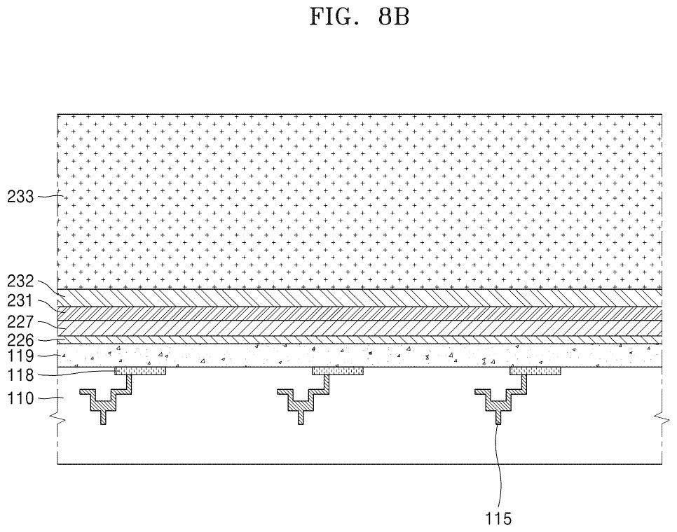

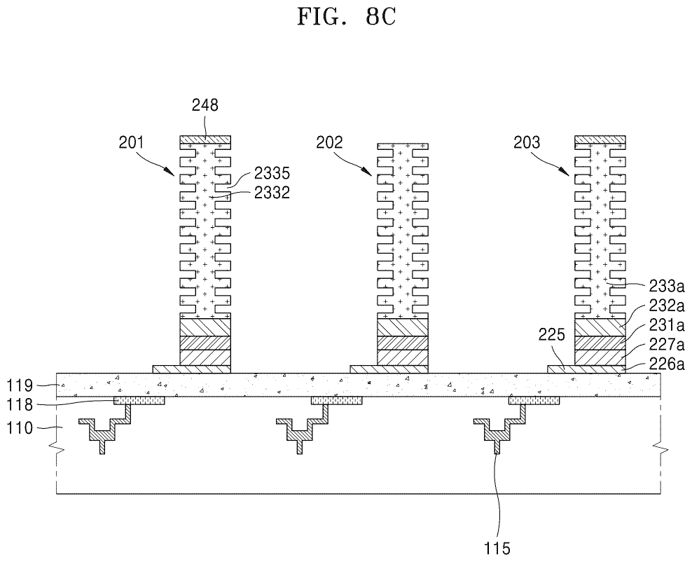

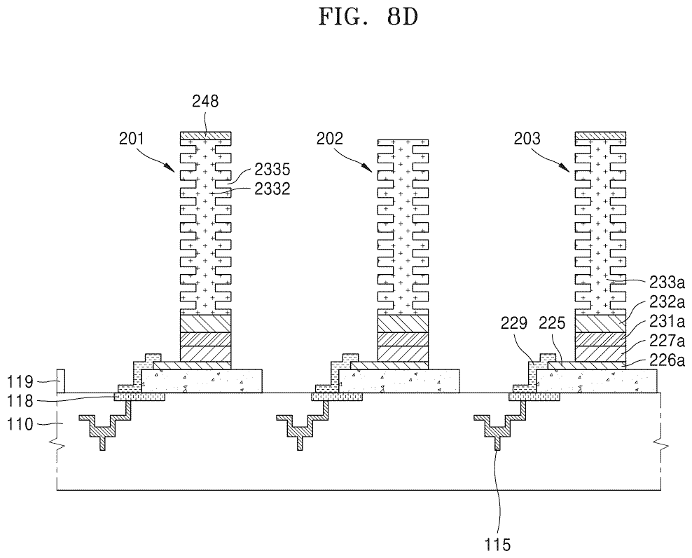

FIGS. 8A to 8D are diagrams illustrating a method of manufacturing a display apparatus according to an embodiment.

In FIGS. 8A to 8D, elements denoted with the same reference numerals as the elements described with reference to FIGS. 6A to 6R may have substantially the same structures as the elements described with reference to FIGS. 6A to 6R and thus repeated decryptions may be omitted.

Referring to FIG. 8A, a stacked structure 210A is bonded to a backplane structure 105A. The backplane structure 105A may have an adhesive layer 119 formed on an upper surface of a backplane substrate 110. The stacked structure 210A may include an etching barrier layer 226, a p-type electrode layer 227, a p-type semiconductor layer 231, an active layer 232, and an n-type semiconductor layer 233.

As shown in FIG. 8B, the backplane structure 105A and the stacked structure 210A may be directly bonded to each other by the adhesive layer 119.

Referring to FIG. 8C, an operation of forming a first light-emitting section 201, a second light-emitting section 202, and a third light-emitting section 203 may be performed in the same manner as described with reference to FIGS. 6D to 6J.

The operation may differ from FIG. 6J in that the etching barrier layer 226 is patterned to form etching barriers 226a. The etching barriers 226a may be wider than p-type semiconductor layers 231a. Therefore, the etching barriers 226a may include portions 225 that extend more than the p-type semiconductor layers 231a. The etching barriers 226a may include ITO.

Next, referring to FIG. 8D, the adhesive layer 119 is etched to expose first bonding layers 118. Thereafter, wiring 229 is formed to connect the first bonding layers 118 and the etching barriers 226a to each other. The wiring 229 is connected between the portions 225 of the etching barriers 226a and the first bonding layers 118 to electrically connect p-type electrodes 227a and driving elements 115 to each other.

Subsequent operations may be performed in the same manner as described with reference to FIGS. 6K to 6R to manufacture a display apparatus.

As described above, according to embodiments, the light conversion efficiency of a color conversion structure of a display apparatus may be improved even with a small amount of quantum dots by embedding quantum dots in nanopores of rod-shaped light-emitting sections and forming a distributed Bragg reflection layer on the rod-shaped light-emitting sections. Nanopores may be selectively formed in rod-shaped n-type semiconductor layers, and quantum dots may be selectively embedded in the nanopores by capillary force.

Quantum dot color converters may be required to have a thickness of about 6 μm or more for light conversion efficiency of 90% or more due to the absorption rate of quantum dots. For example, a pixel density of 5000 ppi or more may be required for augmented reality (AR) glasses. However, it may be very difficult to form quantum dot patterns with such a high aspect ratio. However, in the display apparatus manufacturing methods according to embodiments, quantum dots are embedded in rod-shaped light-emitting sections, and thus, small display apparatuses may be manufactured for AR glasses. In addition, the display apparatuses of the embodiments described above may be applied to various electronic devices.

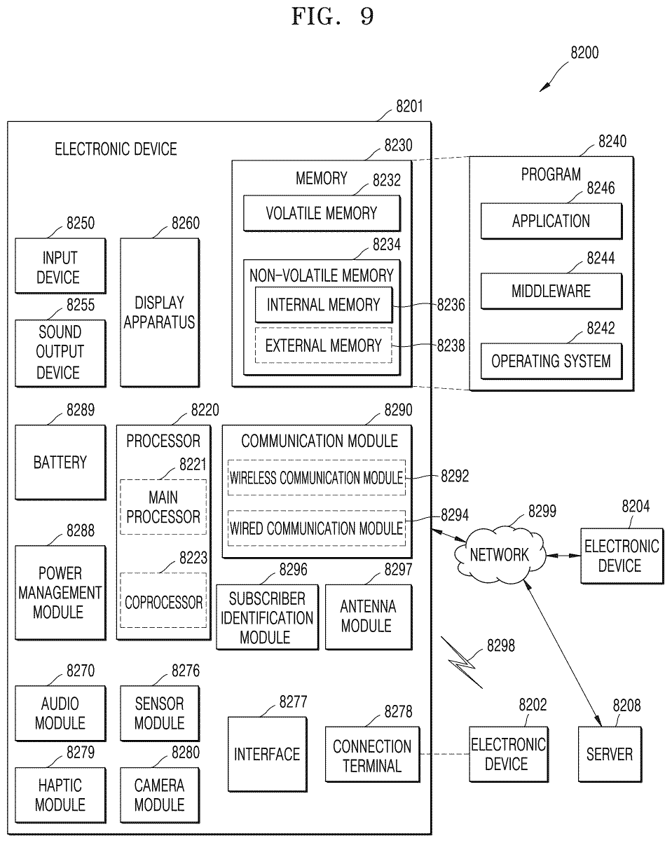

FIG. 9 is a diagram illustrating an electronic device 8201 including a display apparatus 8260 according to an embodiment.

Referring to FIG. 9, the electronic device 8201 may be provided in a network environment 8200. In the network environment 8200, the electronic device 8201 may communicate with another electronic device 8202 through a first network 8298 (such as a short-range wireless communication network) or may communicate with another electronic device 8204 and/or a server 8208 through a second network 8299 (such as a long-range wireless communication network). The electronic device 8201 may communicate with the electronic device 8204 through the server 8208. The electronic device 8201 may include a processor 8220, a memory 8230, an input device 8250, a sound output device 8255, the display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the components of the electronic device 8201 may be omitted, or other components may be added to the electronic device 8201. Some of the components may be implemented as one integrated circuit. For example, the sensor module 8276 (such as a fingerprint sensor, an iris sensor, or an illuminance sensor) may be embedded in the display apparatus 8260 (such as a display).

The processor 8220 may execute software (such as a program 8240) to control one or more other components (such as hardware or software components) of the electronic device 8201 which are connected to the processor 8220, and the processor 8220 may perform various data processing or operations. As part of data processing or computation, the processor 8220 may load commands and/or data received from other components (such as the sensor module 8276, the communication module 8290, etc.) on a volatile memory 8232, process the commands and/or data stored in the volatile memory 8232, and store resulting data in a non-volatile memory 8234. The non-volatile memory 8234 may include an internal memory 8236 and an external memory 8238. The processor 8220 may include: a main processor 8221 (such as a central processing unit, an application processor, etc.), and a coprocessor 8223 (such as a graphics processing unit, an image signal processor, a sensor hub processor, a communication processor, etc.) that may be operated independently or in conjunction with the main processor 8221. The coprocessor 8223 may consume less power than the main processor 8221 and may perform a specialized function.

The coprocessor 8223 may control functions and/or states related to some of the components (such as the display apparatus 8260, the sensor module 8276, and the communication module 8290) of the electronic device 8201, instead of the main processor 8221 while the main processor 8221 is in an inactive state (sleep mode) or together with the main processor 8221 while the main processor 8221 is in an active state (application-execution mode). The coprocessor 8223 (such as an image signal processor, a communication processor, etc.) may be implemented as part of a functionally related component (such as the camera module 8280 or the communication module 8290).

The memory 8230 may store various pieces of data required by the components (such as the processor 8220, the sensor module 8276, etc.) of the electronic device 8201. For example, the data may include: software (such as the program 8240); and instruction input data and/or output data which are related to the software. The memory 8230 may include the volatile memory 8232 and/or the non-volatile memory 8234.

The program 8240 may be stored as software in the memory 8230 and may include an operating system 8242, middleware 8244, and/or an application 8246.

The input device 8250 may receive, from outside the electronic device 8201 (for example, a user), commands and/or data to be used in the components (such as the processor 8220) of the electronic device 8201. The input device 8250 may include a remote controller, a microphone, a mouse, a keyboard, and/or a digital pen (such as a stylus pen).

The sound output device 8255 may output a sound signal to the outside of the electronic device 8201. The sound output device 8255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display apparatus 8260 may provide information to the outside of the electronic device 8201 in a visual manner. The display apparatus 8260 may include a device such as a display, a hologram device, or a projector, and a control circuit for controlling the device. The display apparatus 8260 may include any of the display apparatuses of the embodiments described above. The display apparatus 8260 may include touch circuitry configured to detect touches, and/or a sensor circuit (such as a pressure sensor) configured to measure the magnitudes of forces generated by touches.

The audio module 8270 may convert a sound into an electric signal or may conversely convert an electric signal into a sound. The audio module 8270 may acquire a sound through the input device 8250, or may output a sound through the sound output device 8255 and/or the speaker and/or headphone of another electronic device (such as the electronic device 8202) which are directly or wirelessly connected to the electronic device 8201.

The sensor module 8276 may detect an operating state (such as the power or the temperature) of the electronic device 8201 or an external environmental state (such as a user state) and may generate an electrical signal and/or a data value corresponding to the detected state. The sensor module 8276 may include a gesture sensor, a gyro sensor, a barometric pressure sensor, a magnetic sensor, an accelerometer sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols that may be used by the electronic device 8201 for directly or wirelessly connection with another electronic device (such as the electronic device 8202). The interface 8277 may include a high-definition multimedia Interface (HDMI), a universal serial bus (USB) interface, a secure digital (SD) card interface, and/or an audio interface.

A connection terminal 8278 may include a connector through which the electronic device 8201 may be physically connected to another electronic device (such as the electronic device 8202). The connection terminal 8278 may include an HDMI connector, an USB connector, an SD card connector, and/or an audio connector (such as a headphone connector).

The haptic module 8279 may convert an electrical signal into a mechanical stimulus (such as vibration, movement, etc.) or an electrical stimulus that a user may perceive by the tactile or kinesthetic sense. The haptic module 8279 may include a motor, a piezoelectric element, and/or an electrical stimulation device.

The camera module 8280 may capture still images and moving images. The camera module 8280 may include a lens assembly including one or more lenses, image sensors, image signal processors, and/or flashes. The lens assembly of the camera module 8280 may collect light coming from a subject to be imaged.

The power management module 8288 may manage power supplied to the electronic device 8201. The power management module 8388 may be implemented as part of a power management integrated circuit (PMIC).

The battery 8289 may supply power to the components of the electronic device 8201. The battery 8289 may include non-rechargeable primary cells, rechargeable secondary cells, and/or fuel cells.

The communication module 8290 may support the establishment of a direct (wired) communication channel and/or a wireless communication channel between the electronic device 8201 and another electronic device (such as the electronic device 8202, the electronic device 8204, or the server 8208), and may support communication through the established communication channel. The communication module 8290 may include one or more communication processors that operate independently of the processor 8220 (such as an application processor) and support direct communication and/or wireless communication. The communication module 8290 may include a wireless communication module 8292 (such as a cellular communication module, a short-range wireless communication module, or a global navigation satellite system (GNSS) communication module), and/or a wired communication module 8294 (such as a local area network (LAN) communication module or a power line communication module). The communication modules 8282 and 8294 may communicate with another electronic device through the first network 8298 (for example, a short-range communication network such as Bluetooth, WiFi direct, or infrared data association (IrDA)), or the second network 8299 (for example, a long-range communication network such as a cellular network, the Internet, or a computer network (LAN, WAN, etc.)). Such various types of communication modules may be integrated into one component (single chip, etc.) or may be implemented as a plurality of components (plural chips) separate from each other. The wireless communication module 8292 may identify and authenticate the electronic device 8201 in a communication network such as the first network 8298 and/or the second network 8299 by using subscriber information (such as an international mobile subscriber identifier (IMSI)) stored in the subscriber identification module 8296.

The antenna module 8297 may transmit or receive signals and/or power to or from the outside (for example, other electronic devices). An antenna may include a radiator which has a conductive pattern formed on a substrate (such as a printed circuit board (PCB)). The antenna module 8297 may include one or a plurality of such antennas. When the antenna module 8297 include a plurality of antennas, the communication module 8290 may select one of the plurality of antennas which is suitable for a communication method used in a communication network such as the first network 8298 and/or the second network 8299. Signals and/or power may be transmitted between the communication module 8290 and another electronic device through the selected antenna. In addition to the antennas, other components (such as a radio-frequency integrated circuit (RFIC)) may be included as part of the antenna module 8297.

Some of the components may be connected to each other and exchange signals (such as commands or data) by an inter-peripheral communication scheme (such as a bus, general purpose input and output (GPIO), serial peripheral interface (SPI), or mobile industry processor interface (MIPI)).

Commands or data may be transmitted between the electronic device 8201 and the (external) electronic device 8204 through the server 8208 connected to the second network 8299. The other electronic devices 8202 and 8204 and the electronic device 8201 may be the same type of electronic device or may be different types of electronic devices. All or some of operations of the electronic device 8201 may be executed in one or more of the other electronic devices 8202 and 8204, and the server 8208. For example, when the electronic device 8201 needs to perform a certain function or service, the electronic device 8201 may request one or more other electronic devices to perform a part or all of the function or service instead of performing the function or service by itself. The one or more other electronic devices receiving the request may perform an additional function or service related to the request, and may transmit results thereof to the electronic device 8201. To this end, cloud computing, distributed computing, and/or client-server computing techniques may be used.

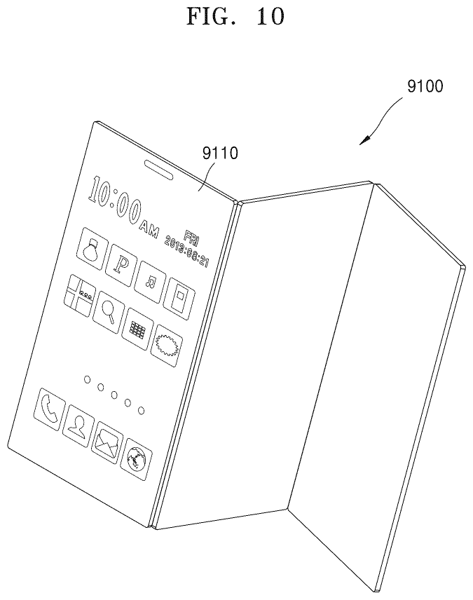

FIGS. 10-14 show examples of devices that may implement a display apparatus such as the display apparatuses described herein.

FIG. 10 is a diagram illustrating a mobile device in which a display apparatus is applied according to an embodiment. The mobile device 9100 may include a display apparatus 9110, and the display apparatus 9110 may include any of the display apparatuses of the embodiments described above. The display apparatus 9110 may have a foldable structure such as a multi-foldable structure.

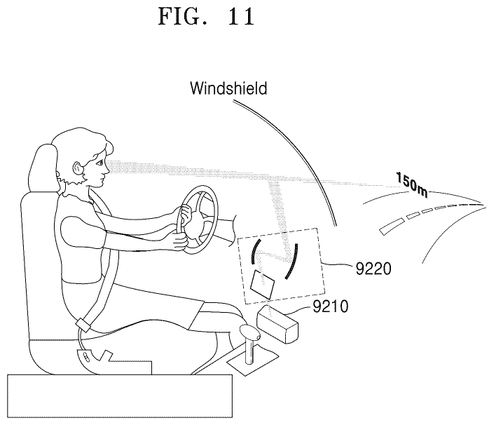

FIG. 11 is a diagram illustrating a vehicle display apparatus in which a display apparatus is applied according to an embodiment. The display apparatus may be a vehicular head-up display apparatus 9200, and may include a display 9210 provided in a region of the vehicle; and an optical passage changing member 9220 configured to change the optical passage of light such that a driver may see images generated by the display 9210.

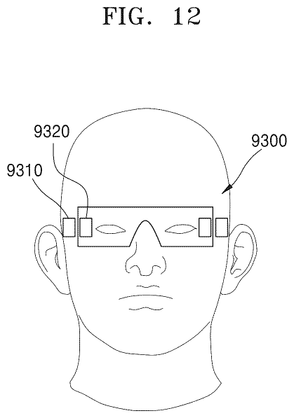

FIG. 12 is a diagram illustrating AR glasses or virtual reality (VR) glasses in which a display apparatus is applied according to an embodiment. The glasses 9300 may include a projection system 9310 configured to form images; and elements 9320 configured to guide the images from projection system 9310 into the eyes of a user. The projection system 9310 may include any of the display apparatuses of the embodiments described above.

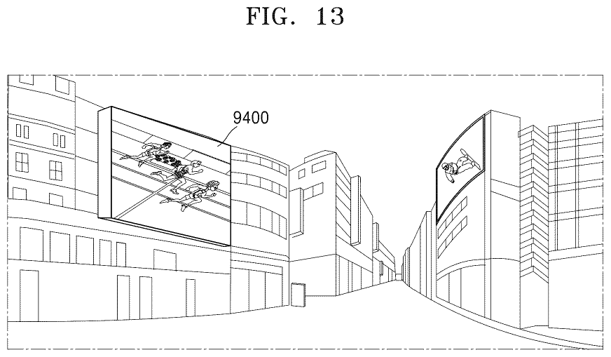

FIG. 13 is a diagram illustrating signage in which a display apparatus is applied according to an embodiment. The signage 9400 may be used for outdoor advertisement using a digital information display and may control advertisement content and the like through a communication network. For example, the signage 9400 may be implemented through the electronic device 8201 described with reference to FIG. 22.

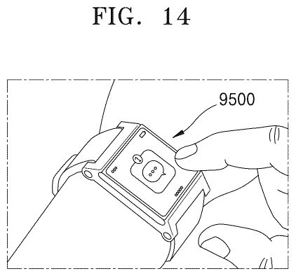

FIG. 14 is a diagram illustrating a wearable display in which a display apparatus is applied according to an embodiment. The wearable display 9500 may include any of the display apparatuses of the embodiments described above may be implemented through the electronic device 8201 described with reference to FIG. 9.

The display apparatuses of the embodiments may be applied to various products such as a rollable television (TV) and a stretchable display.

As described above, according to the one or more of the above embodiments, the display apparatus includes quantum dots embedded in nanopores such that the EQE of the display apparatus may be increased for high luminous efficiency. According to the display apparatus manufacturing methods of the embodiments, rod-type light-emitting sections may be monolithically formed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a backplane substrate comprising driving elements; and
a first light-emitting section, a second light-emitting section, and a third light-emitting section spaced apart from each other on the backplane substrate, the first light-emitting section being configured to emit light of a first wavelength, the second light-emitting section being configured to emit light of a second wavelength, and the third light-emitting section being configured to emit light of a third wavelength,
wherein each of the first light-emitting section, the second light-emitting section and the third light-emitting section comprises a p-type semiconductor layer, an active layer configured to emit blue light, and an n-type semiconductor layer stacked in a direction perpendicular to an upper surface of the backplane substrate, and
wherein each of the n-type semiconductor layers of the first light-emitting section and the third light-emitting section comprises a core rod, a plurality of nanopores respectively comprising an opening and extending from the core rod, and quantum dots in the plurality of nanopores.

2. The display apparatus of claim 1, wherein the quantum dots of the first light-emitting section are configured to convert blue light into red light, and
wherein the quantum dots of the third light-emitting section are configured to convert blue light into green light.

3. The display apparatus of claim 1, further comprising:
p-type electrodes between the backplane substrate and respective p-type semiconductor layers; and
an n-type electrode commonly connected to the first light-emitting section, the second light-emitting section and the third light-emitting section.

4. The display apparatus of claim 1, further comprising a first bonding layer between the backplane substrate and the first light-emitting section, a second bonding layer between the backplane substrate and the second light-emitting section, and a third bonding layer between the backplane substrate and the third light-emitting section.

5. The display apparatus of claim 1, wherein the plurality of nanopores of each of the first light-emitting section and the third light-emitting section extend radially outward from each respective core rod.

6. The display apparatus of claim 1, wherein the plurality of nanopores of each of the first light-emitting section and the third light-emitting section are substantially aligned along a vertical direction.

7. The display apparatus of claim 1, wherein each of the active layers comprises InGaN or InAlGaN.

8. The display apparatus of claim 1, wherein each of the first light-emitting section, the second light-emitting section and the third light-emitting section has a diameter in a range of 0.5 μm to 2 μm.

9. The display apparatus of claim 1, wherein each of the first light-emitting section, the second light-emitting section and the third light-emitting section has a height in a range of 2 μm to 7 μm.

10. The display apparatus of claim 1, wherein each of the core rods has a diameter in a range of ⅓ to ⅕ of a diameter of a respective light-emitting section.

11. The display apparatus of claim 1, wherein each of the core rods has a diameter in a range of 120 nm to 200 nm.

12. The display apparatus of claim 1, further comprising a distributed Bragg reflection layer surrounding side walls of the first light-emitting section, the second light-emitting section and the third light-emitting section,
wherein the distributed Bragg reflection layer has a first reflectivity for blue light and a second reflectivity for green light and red light, the second reflectivity being lower than the first reflectivity.

13. The display apparatus of claim 1, further comprising reflection layers respectively on the n-type semiconductor layers of the first light-emitting section and the third light-emitting section,
wherein the reflection layers comprise aluminum (Al) or silver (Ag).

14. The display apparatus of claim 1, further comprising etching barriers between the backplane substrate and respective p-type semiconductor layers.

15. The display apparatus of claim 14, wherein the etching barriers comprise indium tin oxide (ITO).

16. A method of manufacturing a display apparatus, the method comprising:
preparing a backplane substrate comprising a driving element and a first bonding layer;
forming a stacked structure by depositing an active layer, a p-type semiconductor layer, and a second bonding layer on an n-type semiconductor layer;
bonding the backplane substrate to the stacked structure in a state in which the first bonding layer of the backplane substrate faces the second bonding layer of the stacked structure;
forming a first light-emitting section, a second light-emitting section, and a third light-emitting section that are spaced apart from each other by patterning the n-type semiconductor layer, the active layer, and the p-type semiconductor layer into a rod shape;
forming a core rod and a plurality of nanopores in the n-type semiconductor layer of each of the first light-emitting section, the second light-emitting section and the third light-emitting section through an electrochemical etching process, the plurality of nanopores comprising an opening and extending from the core rod;
forming a quantum dot patterning layer on the first light-emitting section, the second light-emitting section and the third light-emitting section;
removing the quantum dot patterning layer from the first light-emitting section and forming quantum dots in the plurality of nanopores of the first light-emitting section; and
removing the quantum dot patterning layer from the third light-emitting section and forming quantum dots in the plurality of nanopores of the third light-emitting section.

17. The method of claim 16, wherein the quantum dots of the first light-emitting section are configured to convert blue light into red light, and
wherein the quantum dots of the third light-emitting section are configured to convert blue light into green light.

18. The method of claim 16, wherein a p-type electrode is provided between the backplane substrate and the p-type semiconductor layer, and
wherein an n-type electrode is commonly connected to the first light-emitting section, the second light-emitting section and the third light-emitting section.

19. The method of claim 16, wherein the plurality of nanopores of each of the first light-emitting section and the third light-emitting section extend radially outward from the core rod.

20. The method of claim 16, wherein the plurality of nanopores of each of the first light-emitting section and the third light-emitting section are substantially aligned along a vertical direction.
